(19) United States
(12) Patent Application Publication
(10) Pub. No.: US 2026/0324401 A1
(43) Pub. Date: Oct. 15, 2026

(54) SEMICONDUCTOR INTEGRATED CIRCUIT DEVICE

(71) Applicant: Socionext Inc., Kanagawa (JP)

(72) Inventor: Hideyuki KOMURO, Yokohama-shi (JP)

(21) Appl. No.: 19/701,218

(22) Filed: Jun. 8, 2026

Related U.S. Application Data
(63) Continuation of application No. PCT/JP2024/030096, filed on Aug. 23, 2024.

(30) Foreign Application Priority Data
Dec. 14, 2023 (JP) 2023-211278

(51) Int. Cl. H10W 20/43; H03K 17/041; H03K 19/017; H10D 30/00; H10D 30/43; H10D 62/10; H10D 84/85; H10D 89/10; H10W 20/40; H10W 20/41; H10W 20/42

(52) U.S. Cl. CPC H10W 20/43; H10D 30/43; H10D 30/502; H10D 62/121; H10D 84/851; H10D 89/10; H10W 20/422; H10W 20/427; H10W 20/435; H10W 20/498; H03K 17/04106; H03K 19/017

(57) ABSTRACT

A standard cell includes: an active region; an active region formed above the active region and overlapping with the active region in plan view; and a power supply line formed in a back wiring layer. A surface of each of nanosheets that is located on a first side which is one side in a second direction is exposed from a gate line. The power supply line is disposed at an end portion of the standard cell that is located on the first side.

### CROSS-REFERENCE TO RELATED APPLICATIONS

This is a continuation of International Application No. PCT/JP2024/030096 filed on Aug. 23, 2024, which claims priority to Japanese Patent Application No. 2023-211278 filed on Dec. 14, 2023. The entire disclosures of these applications are incorporated by reference herein.

### BACKGROUND

The present disclosure relates to a semiconductor integrated circuit device including a standard cell (hereinafter also simply referred to as a cell as necessary) including a complementary FET (CFET).

A standard cell method is known as a method of forming a semiconductor integrated circuit on a semiconductor substrate. The standard cell method is a method of designing an LSI chip by preparing standard cells in advance including basic units (for example, an inverter, a latch, a flip-flop, a full adder, and others) with specific logic functions; then disposing the plurality of standard cells on the semiconductor substrate; and then connecting the standard cells by lines.

Further, the gate length of a transistor which is a basic component of an LSI has been reduced (scaling), thereby achieving an improved integration degree, a reduced operating voltage, and an improved operating speed. However, an off-current due to excessive scaling and a significant increase in power consumption due to the off-current have been concerned in recent years. To solve these problems, many studies have been conducted on a transistor with a three-dimensional structure developed from a traditional planar type structure. As one of the transistors with the three-dimensional structure, a nanosheet FET is attracting attention.

United States Patent Application Publication No. 2022/0123023 discloses a standard cell using a complementary FET (CFET) in which a P-type nanosheet transistor and an N-type nanosheet transistor are stacked on a substrate in order to reduce the area of a semiconductor integrated circuit device. United States Patent Application Publication No. 2022/0123023 discloses that a line is provided on a back surface just below the transistor and this line is connected with the source and drain of the transistor.

United States Patent Application Publication No. 2022/0246644 discloses a standard cell using a forksheet transistor in which a gate electrode in the nanosheet FET is formed into a fork shape in order to reduce the area of a semiconductor integrated circuit device. United States Patent Application Publication No. 2022/0246644 discloses the structure of a terminal cell in the standard cell using the forksheet transistor.

### SUMMARY

However, regarding a standard cell using a CFET, nothing specific has been considered yet about a layout structure of a standard cell using a forksheet transistor rather than a nanosheet transistor.

Regarding a standard cell using a CFET, an object of the present disclosure is to provide the layout of a semiconductor integrated circuit device including a standard cell using a forksheet transistor as a transistor.

A first aspect of the present disclosure is directed to a semiconductor integrated circuit device including: a plurality of standard cells including a first standard cell, wherein the first standard cell includes a first active region forming a channel, a source, and a drain of a first transistor of a first conductivity type and including a first nanosheet extending in a first direction as the channel, a second active region formed above the first active region in a depth direction; overlapping with the first active region in plan view; forming a channel, a source, and a drain of a second transistor of a second conductivity type different from the first conductivity type; and including a second nanosheet extending in the first direction as the channel, a first gate line extending in a second direction perpendicular to the first direction and the depth direction and surrounding outer peripheries of the first nanosheet and the second nanosheet in the second direction and the depth direction, and a first power supply line formed on a back surface side of the first transistor; extending in the first direction; and supplying a first power supply voltage, a surface of each of the first nanosheet and the second nanosheet that is located on a first side which is one side in the second direction is exposed from the first gate line, and the first power supply line is disposed at an end portion of the first standard cell that is located on the first side.

According to the present disclosure, in plan view, the first power supply line is disposed on part of the first standard cell that is located on the first side which is one side in the second direction. Accordingly, by the first standard cell being disposed in the circuit block, the first standard cell can be shared with the standard cell disposed on part of the first standard cell that is located on the first side and the first power supply line. Thus, the power supply lines for supplying the power supply voltages can be reinforced. Therefore, it is possible to reduce a decrease in the power supply voltage, and also it is possible to reduce occurrence of electromigration due to current concentration.

A second aspect of the present disclosure is directed to a semiconductor integrated circuit device including: a plurality of standard cells including a first standard cell, wherein the first standard cell includes a first active region forming a channel, a source, and a drain of a first transistor of a first conductivity type and including a first nanosheet extending in a first direction as the channel, a second active region formed above the first active region in a depth direction; overlapping with the first active region in plan view; forming a channel, a source, and a drain of a second transistor of a second conductivity type different from the first conductivity type; and including a second nanosheet extending in the first direction as the channel, a first gate line extending in a second direction perpendicular to the first direction and the depth direction and surrounding outer peripheries of the first nanosheet and the second nanosheet in the second direction and the depth direction, and a first power supply line formed on a back surface side of the first transistor; extending in the first direction; and supplying a first power supply voltage, a surface of each of the first nanosheet and the second nanosheet that is located on a first side which is one side in the second direction is exposed from the first gate line, and the first power supply line is disposed at an end portion of the first standard cell that is located on a second side which is the other side in the second direction.

According to the present disclosure, in plan view, the first power supply line is disposed on part of the first standard cell that is located on the second side which is the other side in the second direction. Accordingly, by the first standard cell being disposed in the circuit block, the first standard cell can be shared with the standard cell disposed on part of the first standard cell that is located on the second side and the first power supply line. Thus, the power supply lines for supplying the power supply voltages can be reinforced. Therefore, it is possible to reduce a decrease in the power supply voltage, and also it is possible to reduce occurrence of electromigration due to current concentration.

Regarding a standard cell using a CFET, the present disclosure provides the layout of a semiconductor integrated circuit device including a standard cell using a forksheet transistor as a transistor, where it is possible to reduce a decrease in the power supply voltage, and also it is possible to reduce occurrence of electromigration due to current concentration.

### BRIEF DESCRIPTION OF THE DRAWINGS

FIG. 1 is a plan view showing a layout example of a circuit block provided in a semiconductor integrated circuit device according to a first embodiment.

FIG. 2 is a plan view showing an example of the layout structure of an inverter cell according to the first embodiment.

FIG. 3 is a sectional view of the inverter cell of FIG. 2.

FIG. 4 is a sectional view of the inverter cell of FIG. 2.

FIG. 5 is another configuration example of the semiconductor integrated circuit device according to the first embodiment.

FIG. 6 is a plan view showing an example of the layout structure of the inverter cell according to a variation of the first embodiment.

FIG. 7 is a plan view showing an example of the layout structure of a 2-input NAND cell according to the first embodiment.

FIG. 8 is a plan view showing an example of the layout structure of a 2-input NOR cell according to the first embodiment.

FIG. 9 is a circuit diagram of the standard cells of FIG. 7 and FIG. 8

FIG. 10 is a plan view showing a layout example of a circuit block provided in a semiconductor integrated circuit device according to a second embodiment.

FIG. 11 is a plan view showing an example of the layout structure of an inverter cell according to the second embodiment.

FIG. 12 is a plan view showing an example of the layout structure of a 2-input NAND cell according to the second embodiment.

FIG. 13 is a plan view showing an example of the layout structure of a 2-input NOR cell according to the second embodiment.

### DETAILED DESCRIPTION

Embodiments will be described below with reference to the drawings. In the following embodiments, a semiconductor integrated circuit device includes a plurality of standard cells. It is assumed that at least some of the plurality of standard cells include a forksheet transistor having a gate electrode in a fork shape among nanosheet FETs and further have a CFET structure in which transistors of different conductivity types (in the embodiments, a cell lower portion is of a P conductivity type, and a cell upper portion is of an N conductivity type) are stacked on each other.

In this specification, “VDD” and “VSS” indicate a power supply voltage or a power source itself. In this specification, expressions indicating that the widths and the like are the same, such as “the same line width”, shall be understood to include manufacturing tolerances.

### First Embodiment

### Configuration of Circuit Block

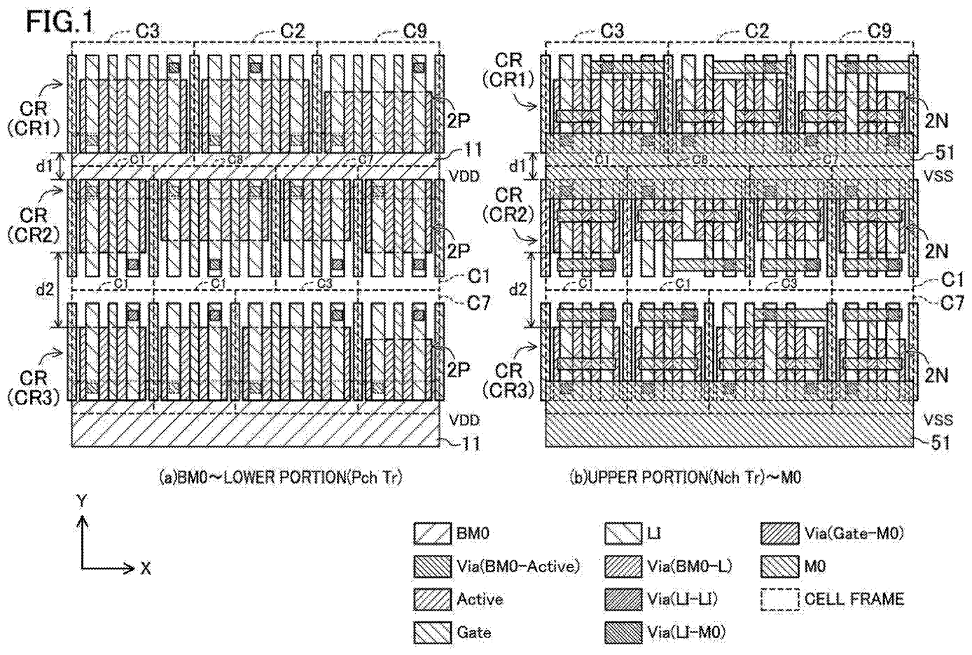

FIG. 1 is a plan view showing an example of the layout of a circuit block in the semiconductor integrated circuit device according to a first embodiment. Specifically, FIG. 1(a) shows a portion including a forksheet transistor formed in a cell lower portion, that is, on the side close to a substrate, and FIG. 1(b) shows a portion including a forksheet transistor formed in a cell upper portion, that is, on the side distant from the substrate.

The block layout of FIG. 1 is formed by disposing the standard cells. In this embodiment, a power supply line is formed in a backside metal 0 (BM0) wiring layer, which is a back wiring layer provided on the back surface of a semiconductor chip on which a transistor is formed, and a M0 wiring layer, which is a metal wiring layer above the transistor.

In the following description, in the plan view of FIG. 1 and others, the lateral direction of the drawing is the X direction (or the first direction), the longitudinal direction of the drawing is the Y direction (or the second direction), and the direction perpendicular to a substrate surface is the Z direction (or the depth direction). Further, in the following description, the same reference characters represent the same elements, and the descriptions thereof may be omitted.

In the plan view of FIG. 1 and others, a dotted line that surrounds the cell indicates a cell frame of the standard cell (an outer edge of the standard cell). The standard cell is disposed so that its cell frame is in contact with a cell frame of an adjacent cell in the X direction or the Y direction.

In the layout of FIG. 1, a plurality of cells arranged in the X direction form cell rows CR (CR1 to CR3). The plurality of cell rows CR (three rows in FIG. 1) are arranged in the Y direction. The plurality of cells include cells having logic functions, such as an inverter, a NAND gate, and a NOR gate. For example, the plurality of cells include inverter cells C1, C7; 2-input NAND cells C2, C8; 2-input NOR cells C3, C9; and the like, each described later.

In each cell, power supply lines are formed in the BM0 wiring layer and the M0 wiring layer. Specifically, a power supply line (a power supply line 11 described later) for supplying a power supply voltage VDD is formed in the BM0 wiring layer, and a power supply line (a power supply line 51 described later) for supplying a power supply voltage VSS is formed in the M0 wiring layer. Each cell is supplied with the power supply voltages VDD, VSS from the outside through these power supply lines. The cell rows CR are disposed so that they are alternately inverted in the Y direction.

In the cell row CR1, CR3, a power supply line 11 (51) is formed at a lower end portion in the Y direction in the drawing. In the cell row CR2, a power supply line 11 (51) is formed at an upper end portion in the Y direction in the drawing. At a cell boundary, the cell rows CR1, CR2 adjacent to each other in the Y direction share the power supply line 11 (51) continuous in the X direction. That is, in the block layout of FIG. 1, the cell rows CR adjacent to each other in the Y direction share the power supply line formed at the cell boundary. Since the cell rows CR adjacent to each other in the Y direction share the power supply line, the power supply line is reinforced. Therefore, it is possible to reduce a decrease in the power supply voltage, and also it is possible to reduce occurrence of electromigration due to current concentration.

An active region 2P that forms the channel, source, and drain of a P-type transistor is formed in the lower portion of each cell. An active region 2N that forms the channel, source, and drain of an N-type transistor is formed in the upper portion of each cell. In the cell row CR, the active regions 2P are aligned in the X direction, and the active regions 2N are aligned in the X direction.

Although the details will be described later, in the standard cell disposed in the cell row CR1, the active region 2P (2N) contains a nanosheet of which the surface located on the upper side in the Y direction in the drawing is not exposed from a gate line, and the surface located on the lower side in the Y direction in the drawing is exposed from a gate line. In the standard cell disposed in the cell row CR2, the active region 2P (2N) contains a nanosheet of which the surface located on the upper side in the Y direction in the drawing is exposed from a gate line, and the surface located on the lower side in the Y direction in the drawing is not exposed from a gate line. In the standard cell disposed in the cell row CR3, the active region 2P (2N) contains a nanosheet of which the surface located on the upper side in the Y direction in the drawing is not exposed from a gate line, and the surface located on the lower side in the Y direction in the drawing is exposed from a gate line. That is, in the block layout of FIG. 1, the cells adjacent to each other in the Y direction are disposed so that the nanosheets in the active regions face each other in the Y direction while the surfaces exposed from the gate line face each other in the Y direction and the surfaces not exposed from the gate line face each other in the Y direction. Specifically, the nanosheet in the active region 2P (2N) of the standard cell disposed in the cell row CR1 and the nanosheet in the active region 2P (2N) of the standard cell disposed in the cell row CR2 are disposed so that the surfaces facing each other in the Y direction are exposed from the gate line. The nanosheet in the active region 2P (2N) of the standard cell disposed in the cell row CR2 and the nanosheet in the active region 2P (2N) of the standard cell disposed in the cell row CR3 are disposed so that the surfaces facing each other in the Y direction are not exposed from the gate line. Accordingly, it is possible to shorten the distance d1 between the active region 2P (2N) of the standard cell disposed in the cell row CR1 and the active region 2P (2N) of the standard cell disposed in the cell row CR2, and therefore it is possible to reduce the area of the semiconductor integrated circuit device. In other words, the distance d1 between the active region 2P (2N) of the standard cell disposed in the cell row CR1 and the active region 2P (2N) of the standard cell disposed in the cell row CR2 is smaller than the distance d2 between the active region 2P (2N) of the standard cell disposed in the cell row CR2 and the active region 2P (2N) of the standard cell disposed in the cell row CR3.

The standard cells disposed in the cell row CR1 are disposed so that in the active region 2P (2N), the lower ends located on the lower side in the drawing are disposed at the same position in the Y direction. The standard cells disposed in the cell row CR2 are disposed so that in the active region 2P (2N), the upper ends located on the upper side in the drawing are disposed at the same position in the Y direction. The standard cells disposed in the cell row CR3 are disposed so that in the active region 2P (2N), the lower ends located on the lower side in the drawing are disposed at the same position in the Y direction. That is, in the cell row CR1, the lower ends of the active regions 2P (2N) that are located on the lower side in the Y direction in the drawing are aligned. In the cell row CR2, the upper ends of the active regions 2P (2N) that are located on the upper side in the Y direction in the drawing are aligned. In the cell row CR3, the lower ends of the active regions 2P (2N) that are located on the lower side in the Y direction in the drawing are aligned. In the standard cell disposed in the cell row CR1, the active region 2P (2N) contains the nanosheet of which the surface located on the lower side in the Y direction in the drawing is exposed from the gate line. In the standard cell disposed in the cell row CR2, the active region 2P (2N) contains the nanosheet of which the surface located on the upper side in the Y direction in the drawing is exposed from the gate line. In the standard cell disposed in the cell row CR3, the active region 2P (2N) contains the nanosheet of which the surface located on the lower side in the Y direction in the drawing is exposed from the gate line. That is, the standard cells disposed in the cell row CR1 are disposed so that the positions of the surfaces of the nanosheets that are exposed from the gate line are aligned in the Y direction. The standard cells disposed in the cell row CR2 are disposed so that the positions of the surfaces of the nanosheets that are exposed from the gate line are aligned in the Y direction. The standard cells disposed in the cell row CR3 are disposed so that the positions of the surfaces of the nanosheets that are exposed from the gate line are aligned in the Y direction. Here, in the forksheet FET, the nanosheets exposed from the gate line and facing each other are formed while a structure comprised of an insulator is provided therebetween. Thus, as in the configuration of FIG. 1, in the cell row in which the standard cells are arranged in the X direction, the positions of the surfaces of the nanosheets that are exposed from the gate line are aligned in the Y direction, so that the shape of the structure, or in other words, the size and installation range of the structure in the Y direction can be made constant. Accordingly, it is possible to facilitate manufacture of the semiconductor integrated circuit device.

### Configuration of Inverter Cell C1

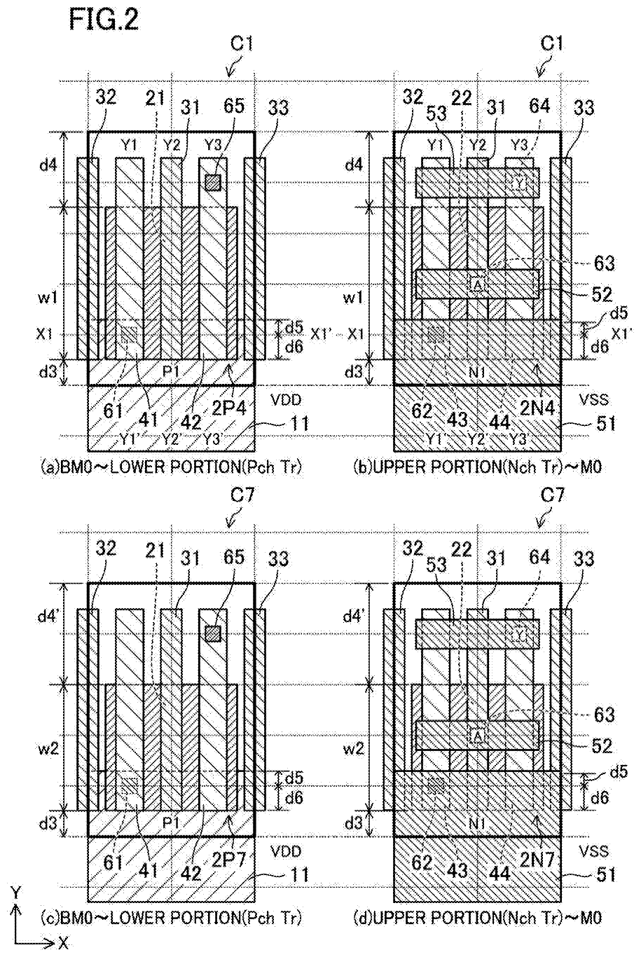

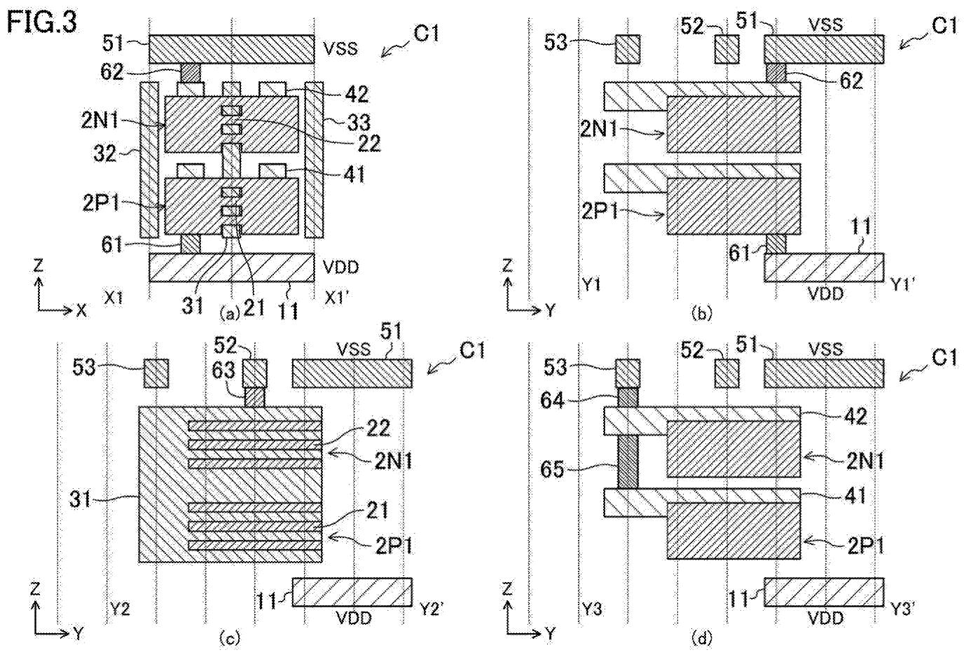

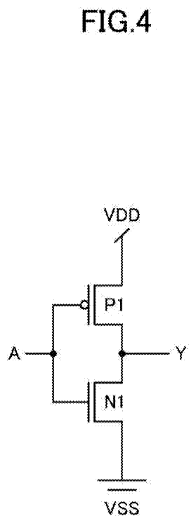

FIG. 2 is a plan view showing an example of layout structures of the inverter cells C1, C7 of the first embodiment; FIG. 3 is a sectional view showing an example of a layout structure of an inverter cell of the first embodiment; and FIG. 4 is a circuit diagram of the inverter cell of the embodiment. Specifically, FIG. 2(a) shows a cell lower portion of the inverter cell C1; FIG. 2(b) shows a cell upper portion of the inverter cell C1; FIG. 2(c) shows a cell lower portion of the inverter cell C7; FIG. 2(d) shows a cell upper portion of the inverter cell C7; FIG. 3(a) shows a cross section taken along line X1-X1′ of FIG. 2(a) and 2(b); FIG. 3(b) shows a cross section taken along line Y1-Y1′ of FIG. 2(a) and 2(b); FIG. 3(c) shows a cross section taken along line Y2-Y2′ of FIG. 2(a) and 2(b); and FIG. 3(d) shows a cross section taken along line Y3-Y3′ of FIG. 2(a) and 2(b).

In the following description, the dashed lines running longitudinally and laterally in the plan views of FIG. 2 and others and the dashed lines running longitudinally in the sectional views of FIG. 2 and others indicate grids used for locating components at the time of designing. The grids are disposed at equal intervals in the X direction, and are disposed at equal intervals in the Y direction. The grid intervals in the X direction may be the same as or may be different from those in the Y direction. The grid intervals may be different in different layers. Further, each component is not necessarily disposed on the grid.

As shown in FIG. 4, the inverter cell C1 has transistors P1, N1, and forms an inverter circuit with an input A and an output Y.

As shown in FIG. 2(a), the BM0 wiring layer, which is a wiring layer, is formed on the back surface of the semiconductor chip on which the transistors are formed. In the BM0 wiring layer, the power supply line 11 extending in the X direction is formed at the lower end potion of the cell in the Y direction in the drawing. The power supply line 11 supplies the power supply voltage VDD.

The active region forming the channel, source, and drain of the P-type transistor is formed in the P-type transistor region in the cell lower portion. Specifically, an active region 2P1 is formed in the P-type transistor region. The active region 2P1 overlaps with the power supply line 11 in plan view.

A P-type transistor P1 is formed in the P-type transistor region. The transistor P1 has a nanosheet 21 as a channel which has a sheet structure with three sheets overlapping with each other in plan view and which extends in the X direction. Part of the active region 2P1 that serves as the source of the transistor P1 is connected with the power supply line 11 through a via 61. The via 61 is formed in a region in which the power supply line 11 and the active region 2P1 overlap with each other in plan view.

As shown in FIG. 2(b), the active region forming the channel, source, and drain of the N-type transistor is formed in the N-type transistor region in the cell upper portion. Specifically, an active region 2N1 is formed in the N-type transistor region. The active region 2N1 is disposed above the active region 2P1 in the Z direction. The active region 2N1 overlaps with the active region 2P1 in plan view.

An N-type transistor N1 is formed in the N-type transistor region. The transistor N1 has a nanosheet 22 as a channel which has a sheet structure with three sheets overlapping with each other in plan view and which extends in the X direction.

In the active region, portions that serve as the source and the drain on both sides of the nanosheet are formed by epitaxial growth of the nanosheet, for example.

At the center portion of the cell in the X direction in the drawing, a gate line 31 extending in the Y direction and extending in the Z direction from the cell upper portion to the cell lower portion is formed. The nanosheets 21, 22 overlap with the gate line 31 in plan view. The gate line 31 corresponds to the gates of the transistors P1, N1.

As shown in FIG. 3(c), the gate line 31 covers the outer peripheries of the nanosheets 21, 22 in the Y direction and the Z direction so that part of the outer peripheries of the nanosheets 21, 22 is exposed. Specifically, the side surfaces of the nanosheets 21, 22 that are located on the right side in the drawing are not covered with the gate line 31. That is, the side surfaces of the nanosheets 21, 22 that are located on the right side in the drawing are exposed from the gate line 31. Therefore, in FIG. 2, part of each of the nanosheets 21, 22 that is located on the lower side in the Y direction in the drawing is exposed from the gate line 31, and part of each of the nanosheets 21, 22 that is located on the upper side in the Y direction in the drawing is covered with the gate line 31.

As shown in FIG. 2, dummy gate lines 32, 33 extending in the Y direction and the Z direction are formed on the cell frames on both sides in the X direction. The dummy gate line 32 is shared with other cells disposed on the left side in the drawing. The dummy gate line 33 is shared with other cells disposed on the right side in the drawing.

As shown in FIG. 2(a), a local line (LI: local interconnect) 41 extending in the Y direction is formed in the cell lower portion. The local line 41 is connected to part of the active region 2P1 that serves as the drain of the transistor P1.

As shown in FIG. 2(b), a local line 42 extending in the Y direction is formed in the cell upper portion. The local line 42 is connected to part of the active region 2N1 that serves as the drain of the transistor N1.

In the M0 wiring layer, which is a metal wiring layer disposed above the active region 2N1, the power supply line 51 and lines 52, 53 extending in the X direction are formed. The power supply line 51 supplies the power supply voltage VSS. The line 52 corresponds to the input A, and the line 53 corresponds to the output Y.

The power supply line 51 is formed at a lower end portion of the cell in the Y direction in the drawing. The power supply line 51 overlaps with the active region 2N1 in plan view. Through a via 62 and the local line, the power supply line 51 is connected with part of the active region 2N1 that serves as the source of the transistor N1. The via 62 is formed in a region in which the power supply line 51 and the active region 2N1 overlap with each other in plan view.

The line 52 is disposed near the center portion of the cell in the Y direction in the drawing. The line 52 is connected with the gate line 31 through a via 63. The via 63 is formed in a region in which the line 52 and the active region 2N1 overlap with each other in plan view.

The line 53 is disposed on the upper side in the Y direction in the drawing. Through vias 64, 65 and the local lines 41, 42, the line 53 is connected with a portion that serves as the drain of the transistor P1 and a portion that serves as the drain of the transistor N1.

As described above, the inverter cell C1 has the P-type transistor P1 and the N-type transistor N1, and forms the inverter circuit with the input A and the output Y.

As shown in FIG. 2(a) and 2(b), the active region 2P1, 2N1 in the inverter cell C1 has a width w1 in the Y direction in plan view.

In the inverter cell C1 shown in FIG. 2, the surfaces of the nanosheets 21, 22 that are located on the lower side in the Y direction in the drawing are exposed from the gate line 31. The cell rows CR are disposed so that they are alternately inverted in the Y direction. That is, the cells adjacent to each other in the Y direction are disposed so that the nanosheets in the active regions face each other in the Y direction while the surfaces exposed from the gate line (the surfaces located on the lower side in the drawing) face each other in the Y direction. Accordingly, it is possible to shorten the distance d3 from the lower end of the active region 2P1 (2N1) in the Y direction in the drawing to the lower end of the cell frame in the Y direction in the drawing. In other words, the active regions 2P1, 2N1 (the nanosheets 21, 22) can be disposed close to the lower end of the cell frame in the Y direction in the drawing. Therefore, the area of the semiconductor integrated circuit device can be reduced.

The surfaces of the nanosheets 21, 22 that are located on the upper side in the Y direction in the drawing are not exposed from the gate line 31. That is, the cells adjacent to each other in the Y direction are disposed so that the nanosheets in the active regions face each other in the Y direction while the surfaces exposed from the gate line (the surfaces located on the lower side in the drawing) face each other in the Y direction, and the surfaces not exposed from the gate line (the surfaces located on the upper side in the drawing) face each other in the Y direction. Thus, the distance d3 from the lower end of the active region 2P1 (2N1) in the Y direction in the drawing to the lower end of the cell frame in the Y direction in the drawing is smaller than the distance d4 from the upper end of the active region 2P1 (2N1) in the Y direction in the drawing to the upper end of the cell frame in the Y direction in the drawing. In other words, in plan view, the active region 2P1 (2N1) is disposed close to the lower end of the cell frame in the drawing with respect to the center of the cell frame in the Y direction in the drawing. That is, in plan view, the center portion of the active region 2P1 (2N1) in the Y direction in the drawing is located on the lower side in the drawing with respect to the center portion of the cell frame in the Y direction in the drawing.

In plan view, the power supply lines 11, 51 are formed at the lower end portion of the cell in the Y direction in the drawing, and are shared with the standard cell disposed on the lower side of the inverter cell C1 in the Y direction in the drawing. Accordingly, by the inverter cell C1 being disposed in the circuit block of FIG. 1, the power supply lines for supplying the power supply voltages VDD, VSS can be reinforced. Therefore, it is possible to reduce a decrease in the power supply voltage, and also it is possible to reduce occurrence of electromigration due to current concentration.

The via 61 that connects the power supply line 11 and part of the active region 2P1 that serves as the source of the transistor P1 is formed in a region in which the power supply line 11 and the active region 2P1 overlap with each other in plan view. In plan view, the via 61 is disposed close to the upper side in the drawing in the region in which the power supply line 11 and the active region 2P1 overlap with each other in plan view. In other words, in plan view, the distance d5 in the Y direction from the center portion of the via 61 in the drawing to the upper end of the power supply line 11 in the drawing is smaller than the distance d6 in the Y direction from the center portion of the via 61 in the drawing to the lower end of the active region 2P1 in the drawing. Accordingly, the via 61 is disposed close to the center portion of the active region 2P1 in the Y direction in the drawing, and therefore the difference is reduced between the resistance value from the via 61 to the upper end of the nanosheet 21 of the transistor P1 in the active region 2P1 in the drawing and the resistance value from the via 61 to the lower end of the nanosheet 21 of the transistor P1 in the active region 2P1 in the drawing. Therefore, the current flowing through the transistor P1 is equalized in the Y direction, or in the up-down direction in the drawing, and thus it is possible to increase the speed of the semiconductor integrated circuit device.

The via 62 that connects the power supply line 51 and part of the active region 2N1 that serves as the source of the transistor N1 is formed in a region in which the power supply line 51 and the active region 2N1 overlap with each other in plan view. In plan view, the via 62 is disposed close to the upper side in the drawing in the region in which the power supply line 51 and the active region 2N1 overlap with each other in plan view. In other words, in plan view, the distance d5 in the Y direction from the center portion of the via 62 in the drawing to the upper end of the power supply line 51 in the drawing is smaller than the distance d6 in the Y direction from the center portion of the via 62 in the drawing to the lower end of the active region 2N1 in the drawing. Accordingly, the via 62 is disposed close to the center portion of the active region 2N1 in the Y direction in the drawing, and therefore the difference is reduced between the resistance value from the via 62 to the upper end of the nanosheet 22 of the transistor N1 in the active region 2N1 in the drawing and the resistance value from the via 62 to the lower end of the nanosheet 22 of the transistor N1 in the active region 2N1 in the drawing. Therefore, the current flowing through the transistor N1 is equalized in the Y direction, or in the up-down direction in the drawing, and thus it is possible to increase the speed of the semiconductor integrated circuit device.

The via 63 that connects the line 52 and the gate line 31 is formed in a region to overlap with the active region 2N1 and the gate line 31 in plan view. Accordingly, it is possible to shorten the distance from the line 52 (the input A) to part of the gate line 31 overlapping with the nanosheets 21, 22 in plan view that covers the nanosheets 21, 22. Therefore, it is possible to reduce a resistance value from the line 52, and thus it is possible to increase the speed of the semiconductor integrated circuit device.

The line 53 is disposed on the upper side in the Y direction in the drawing with respect to the line 52 (the side on which the nanosheet 22 is not exposed from the gate line 31 and which is opposite to the side on which the active region 2N1 is disposed close to the cell frame). The via 64 that connects the line 53 and the local line 42 and the via 65 that connects the local lines 41, 42 are formed on the upper side in the Y direction in the drawing in plan view with respect to the line 52. Accordingly, it is possible to shorten the distance from the line 53 to part of the active region 2P1 that serves as the drain of the transistor P1 and the distance from the line 53 to part of the active region 2N1 that serves as the drain of the transistor N1. Therefore, it is possible to reduce a resistance value from the line 53 to part of the active region 2P1 (2N1) that serves as the drain of the transistor P1 (N1), and thus it is possible to increase the speed of the semiconductor integrated circuit device.

### Configuration of Inverter Cell C7

The inverter cell C7 and the inverter cell C1 have substantially the same configuration. Specifically, the inverter cell C7 has the P-type transistor P1 and the N-type transistor N1, and forms the inverter circuit with the input A and the output Y.

As shown in FIG. 2(c) and 2(d), the inverter cell C7 has an active region 2P7, 2N7 which is different in width in the Y direction from the active region 2P1, 2N1 in the inverter cell C1 shown in FIG. 2(a) and 2(b).

Specifically, the width of the active region 2P7, 2N7 in the Y direction is w2. The width w2 is smaller than the width w1. That is, the drive capability of the inverter cell C1 is greater than the drive capability of the inverter cell C7.

As shown in FIG. 2, the lower end of the active region 2P7 (2N7) in the Y direction in the drawing is disposed at the same position in the Y direction as the lower end of the active region 2P1 (2N1) in the Y direction in the drawing. That is, the lower end of the active region 2P1 (2N1) of the inverter cell C1 in the Y direction in the drawing and the lower end of the active region 2P7 (2N7) of the inverter cell C7 in the Y direction in the drawing are aligned in the Y direction. In the inverter cells C1, C7, the surface of the nanosheet 21 (22) that is located on the lower side in the Y direction in the drawing is exposed from the gate line 31. That is, in the inverter cells C1, C7, the positions of the surfaces of the nanosheets exposed from the gate lines are aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

This embodiment employs an exemplary case in which the two inverter cells of which the active regions are different in width are disposed in the circuit block, but three or more inverter cells of which the active regions are different in width may be disposed in the circuit block. In this case, in each inverter cell, the positions of the surfaces of the nanosheets exposed from the gate line only need to be aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

### Other Configuration Examples

The above-described power supply line formed on the back surface side of the transistor may be configured using a semiconductor chip different from the semiconductor chip in which the transistor is formed.

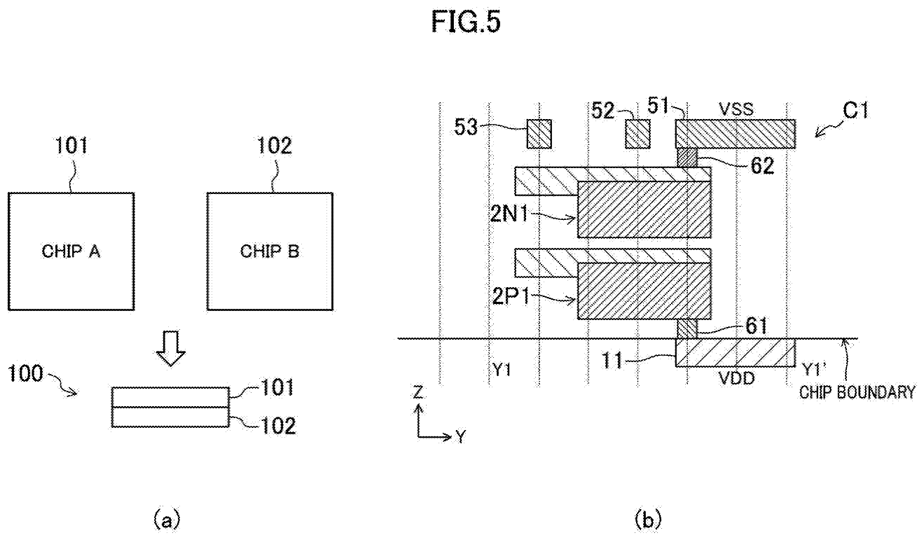

FIG. 5(a) is another configuration example of the semiconductor integrated circuit device of the first embodiment. A semiconductor integrated circuit device 100 shown in FIG. 5(a) is formed of a first semiconductor chip 101 (chip A) and a second semiconductor chip 102 (chip B) stacked on each other. The above-described standard cell and the like including an inverter cell are disposed on the chip A. A power supply line is formed in a wiring layer provided on the surface of the chip B. The chip B is bonded to the back surface side of the chip A using a bump or the like.

FIG. 5(b) shows a cross section of the inverter cell C1 of FIG. 2 taken along line Y1-Y1′ according to this configuration example. As shown in FIG. 5(b), the wiring layer on the surface of the chip B is formed with the power supply line 11 that supplies VDD. The power supply line 11 is connected with the active region 2P1 of the chip A through the via 61.

This configuration example can also provide the same advantages as those of the inverter cell described above.

### Variations

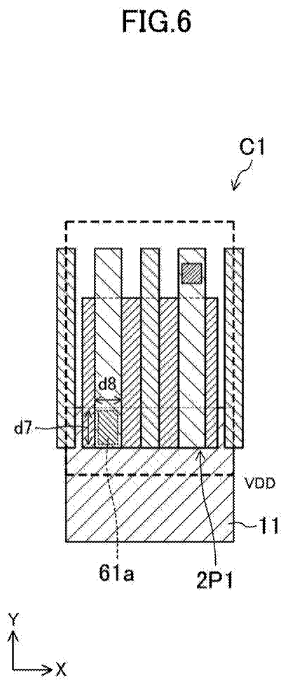

FIG. 6 is a plan view showing an example of the layout structure of the inverter cell according to a variation of the first embodiment. FIG. 6 shows the cell lower portion. In FIG. 6, as compared with FIG. 2(a), a via 61a is disposed instead of the via 61. In plan view, the via 61a is different in shape from the via 61.

The cross section of the via 61a is rectangular in plan view. Specifically, the length d7 of the via 61a in the Y direction is longer than the length d8 in the X direction. In plan view, the length d7 of the via 61a in the Y direction is substantially the same as the length of a region in the Y direction in which the active region 2P1 and the power supply line 11 overlap with each other.

According to the configuration of FIG. 6, the resistance value of the via 61a that connects the power supply line 11 and part of the active region 2P1 that serves as the source of the transistor P1 can be reduced. Therefore, it is possible to reduce a decrease in the power supply voltage, and also it is possible to reduce occurrence of electromigration.

The length d7 of the via 61a in the Y direction is substantially the same as the length of a region in the Y direction in which the active region 2P1 and the power supply line 11 overlap with each other, but the length is not limited to this configuration.

The cell upper portion may be configured similarly to FIG. 6. That is, in FIG. 2(b), a via similar to the via 61a, the length of which is greater in the Y direction than in the X direction, may be used instead of the via 62.

### Other Layout Structures of Standard Cell

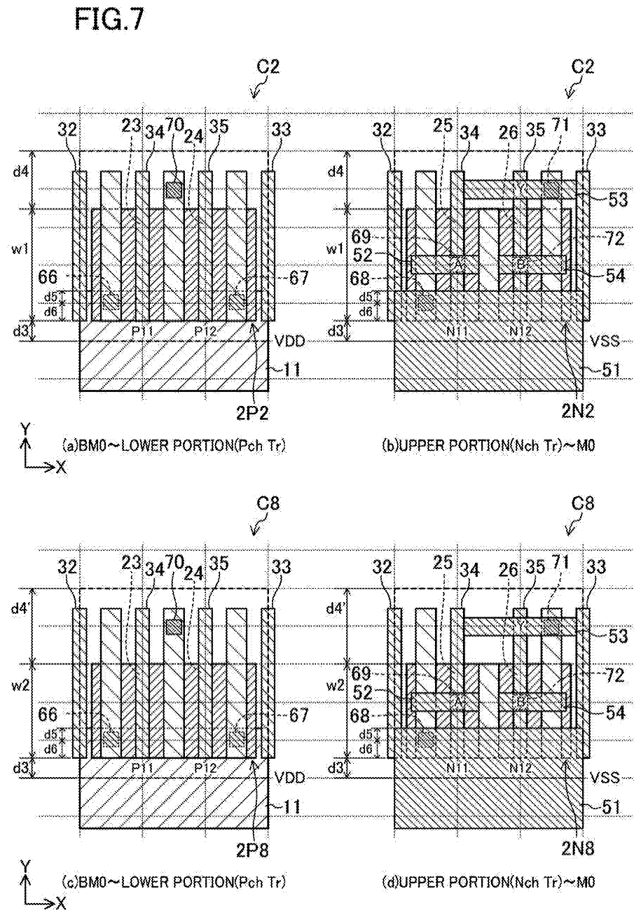

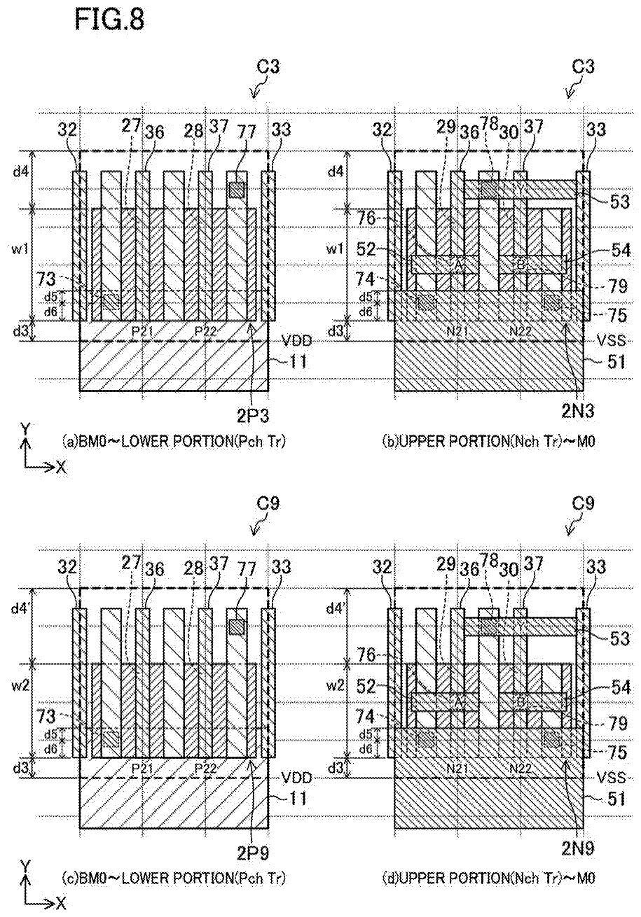

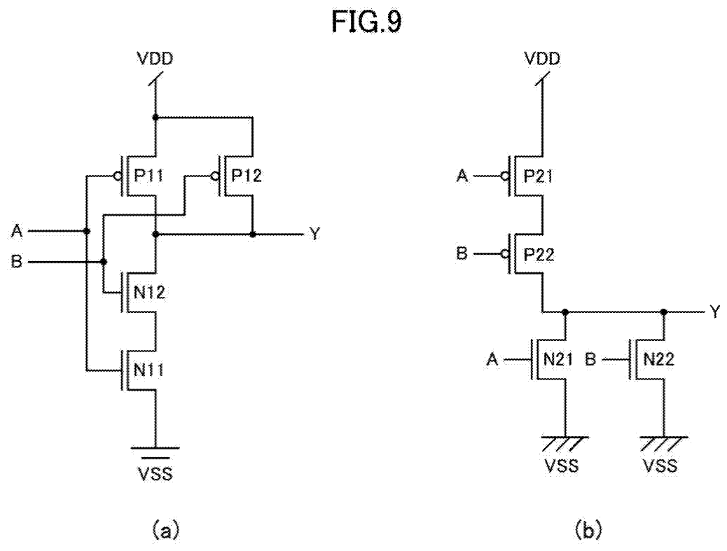

FIGS. 7 and 8 are plan views showing examples of the layout structure of the cell contained in the semiconductor integrated circuit device of the first embodiment. FIG. 7(a) is a cell lower portion of the 2-input NAND cell C2. FIG. 7(b) is a cell upper portion of the 2-input NAND cell C2. FIG. 7(c) is a cell lower portion of the 2-input NAND cell C8. FIG. 7(d) is a cell upper portion of the 2-input NAND cell C8. FIG. 8(a) is a cell lower portion of the 2-input NOR cell C3. FIG. 8(b) is a cell upper portion of the 2-input NOR cell C3. FIG. 8(c) is a cell lower portion of the 2-input NOR cell C9. FIG. 8(d) is a cell upper portion of the 2-input NOR cell C9. FIG. 9(a) is a circuit diagram of the 2-input NAND cell. FIG. 9(b) is a circuit diagram of the 2-input NOR cell.

The layout structures of FIGS. 7 and 8 can be easily understood from the above description of the inverter cell of FIG. 2 and the circuit diagrams of FIG. 9, and therefore, the description thereof will be omitted.

### Configuration of 2-Input NAND Cell C2

As shown in FIG. 7(a), in the BM0 wiring layer, the power supply line 11 extending in the X direction is formed at a lower end portion of the cell in the Y direction in the drawing. The power supply line 11 supplies the power supply voltage VDD.

An active region 2P2 is formed in a P-type transistor region in the cell lower portion. The active region 2P2 overlaps with the power supply line 11 in plan view.

In the active region 2P2, transistors P11, P12 are formed. The transistors P11, P12 have nanosheets 23, 24 extending in the X direction, respectively. Part of the active region 2P2 that serves as the source of the transistor P11, P12 is connected with the power supply line 11 through a via 66, 67. The vias 66, 67 are formed in a region in which the power supply line 11 and the active region 2P2 overlap with each other in plan view.

As shown in FIG. 7(b), an active region 2N2 is formed in an N-type transistor region in the cell upper portion. The active region 2N2 overlaps with the active region 2P2 in plan view.

In the active region 2N2, transistors N11, N12 are formed. The transistors N11, N12 have nanosheets 25, 26 extending in the X direction, respectively.

Gate lines 34, 35 extending in the Y direction are formed. The nanosheets 23, 25 overlap with the gate line 34 in plan view. The nanosheets 24, 26 overlap with the gate line 35 in plan view. The gate line 34 corresponds to the gates of the transistors P11, N11. The gate line 35 corresponds to the gates of the transistors P12, N12.

The gate line 34 covers the outer peripheries of the nanosheets 23, 25 in the Y direction and the Z direction so that part of the outer peripheries of the nanosheets 23, 25 is exposed. The gate line 35 covers the outer peripheries of the nanosheets 24, 26 in the Y direction and the Z direction so that part of the outer peripheries of the nanosheets 24, 26 is exposed. Specifically, the surface of the nanosheets 23, 25 that is located on the lower side in the Y direction in the drawing is exposed from the gate line 34, and the surface of the nanosheets 23, 25 that is located on the upper side in the Y direction in the drawing is covered with the gate line 34. The surface of the nanosheets 24, 26 that is located on the lower side in the Y direction in the drawing is exposed from the gate line 35, and the surface of the nanosheets 24, 26 that is located on the upper side in the Y direction in the drawing is covered with the gate line 35.

The power supply line 51 and the lines 52 to 54 extending in the X direction are formed in the M0 wiring layer. The power supply line 51 supplies the power supply voltage VSS. The line 52 corresponds to the input A, the line 53 corresponds to the output Y, and the line 54 corresponds to the input B.

The power supply line 51 is formed at a lower end portion of the cell in the Y direction in the drawing. The power supply line 51 overlaps with the active region 2N2 in plan view. Through the via 68 and the local line, the power supply line 51 is connected with part of the active region 2N2 that serves as the source of the transistor N11. The via 68 is formed in a region in which the power supply line 51 and the active region 2N2 overlap with each other in plan view.

The line 52 is disposed near a center portion of the cell in the Y direction in the drawing. The line 52 is connected with the gate line 34 through a via 69. The via 69 is formed in a region in which the line 52 and the active region 2N2 overlap with each other in plan view.

The line 53 is disposed in an upper portion of the cell in the Y direction in the drawing. Through vias 70, 71 and the local line, the line 53 is connected with part of the active region 2P2 that serves as the drain of the transistors P11, P12 and part of the active region 2N2 that serves as the drain of the transistor N12.

The line 54 is disposed near a center portion of the cell in the Y direction in the drawing. The line 54 is connected with the gate line 35 through a via 72. The via 72 is formed in a region in which the line 54 and the active region 2N2 overlap with each other in plan view.

As described above, the 2-input NAND cell C2 has the P-type transistors P11, P12 and the N-type transistors N11, N12, and forms the NAND circuit with the inputs A, B and the output Y.

As shown in FIG. 7(a) and 7(b), the active region 2P2, 2N2 in the 2-input NAND cell C2 has a width w1 in the Y direction in plan view.

In the 2-input NAND cell C2 shown in FIG. 7, the surfaces of the nanosheets 23, 25 that are located on the lower side in the Y direction in the drawing are exposed from the gate line 34. The surfaces of the nanosheets 24, 26 that are located on the lower side in the Y direction in the drawing are exposed from the gate line 35. The cell rows CR are disposed so that they are alternately inverted in the Y direction. That is, the cells adjacent to each other in the Y direction are disposed so that the nanosheets in the active regions face each other in the Y direction while the surfaces exposed from the gate line (the surfaces located on the lower side in the drawing) face each other in the Y direction. Accordingly, it is possible to shorten the distance d3 from the lower end of the active region 2P2 (2N2) in the Y direction in the drawing to the lower end of the cell frame in the Y direction in the drawing. In other words, the active regions 2P2, 2N2 (the nanosheets 23 to 26) can be disposed close to the lower end of the cell frame in the Y direction in the drawing. Therefore, the area of the semiconductor integrated circuit device can be reduced.

The surfaces of the nanosheets 23, 25 that are located on the upper side in the Y direction in the drawing are not exposed from the gate line 34. The surfaces of the nanosheets 24, 26 that are located on the upper side in the Y direction in the drawing are not exposed from the gate line 35. That is, the cells adjacent to each other in the Y direction are disposed so that the nanosheets in the active regions face each other in the Y direction while the surfaces exposed from the gate line (the surfaces located on the lower side in the drawing) face each other in the Y direction, and the surfaces not exposed from the gate line (the surfaces located on the upper side in the drawing) face each other in the Y direction. Thus, the distance d3 from the lower end of the active region 2P2 (2N2) in the Y direction in the drawing to the lower end of the cell frame in the Y direction in the drawing is smaller than the distance d4 from the upper end of the active region 2P2 (2N2) in the Y direction in the drawing to the upper end of the cell frame in the Y direction in the drawing. In other words, in plan view, the active region 2P2 (2N2) is disposed close to the lower end of the cell frame in the drawing with respect to the center of the cell frame in the Y direction in the drawing. That is, in plan view, the center portion of the active region 2P2 (2N2) in the Y direction in the drawing is located on the lower side in the drawing with respect to the center portion of the cell frame in the Y direction in the drawing.

In plan view, the power supply lines 11, 51 are formed at the lower end portion of the cell in the Y direction in the drawing, and are shared with the standard cell disposed on the lower side of the 2-input NAND cell C2 in the Y direction in the drawing. Accordingly, by the 2-input NAND cell C2 being disposed in the circuit block of FIG. 1, the power supply lines for supplying the power supply voltages VDD, VSS can be reinforced. Therefore, it is possible to reduce a decrease in the power supply voltage, and also it is possible to reduce occurrence of electromigration due to current concentration.

The via 66 (67) that connects the power supply line 11 and part of the active region 2P2 that serves as the source of the transistor P11 (P12) is formed in a region in which the power supply line 11 and the active region 2P2 overlap with each other in plan view. In plan view, the via 66 (67) is disposed close to the upper side in the drawing in the region in which the power supply line 11 and the active region 2P2 overlap with each other in plan view. In other words, in plan view, the distance d5 in the Y direction from the center portion of the via 66 (67) in the drawing to the upper end of the power supply line 11 in the drawing is smaller than the distance d6 in the Y direction from the center portion of the via 66 (67) in the drawing to the lower end of the active region 2P2 in the drawing. Accordingly, the via 66 (67) is disposed close to the center portion of the active region 2P2 in the Y direction in the drawing, and therefore the difference is reduced between the resistance value from the via 66 (67) to the upper end of the nanosheet 23 (24) of the transistor P11 (P12) in the active region 2P2 in the drawing and the resistance value from the via 66 (67) to the lower end of the nanosheet 23 (24) of the transistor P11 (P12) in the active region 2P2 in the drawing. Therefore, the current flowing through the transistor P11 (P12) is equalized in the Y direction, or in the up-down direction in the drawing, and thus it is possible to increase the speed of the semiconductor integrated circuit device.

The via 68 that connects the power supply line 51 and part of the active region 2N2 that serves as the source of the transistor N11 is formed in a region in which the power supply line 51 and the active region 2N2 overlap with each other in plan view. In plan view, the via 68 is disposed close to the upper side in the drawing in the region in which the power supply line 51 and the active region 2N2 overlap with each other in plan view. In other words, in plan view, the distance d5 in the Y direction from the center portion of the via 68 in the drawing to the upper end of the power supply line 51 in the drawing is smaller than the distance d6 in the Y direction from the center portion of the via 68 in the drawing to the lower end of the active region 2N2 in the drawing. Accordingly, the via 68 is disposed close to the center portion of the active region 2N2 in the Y direction in the drawing, and therefore the difference is reduced between the resistance value from the via 68 to the upper end of the nanosheet 25 of the transistor N11 in the active region 2N2 in the drawing and the resistance value from the via 68 to the lower end of the nanosheet 25 of the transistor N11 in the active region 2N2 in the drawing. Therefore, the current flowing through the transistor N11 is equalized in the Y direction, or in the up-down direction in the drawing, and thus it is possible to increase the speed of the semiconductor integrated circuit device.

The via 69 (72) that connects the line 52 (54) and the gate line 34 (35) is formed in a region to overlap with the active region 2N2 and the gate line 34 (35) in plan view. Accordingly, it is possible to shorten the distance from the line 52 (54) (the input A (the input B)) to part of the gate line 34 (35) overlapping with the nanosheets 23, 25 (24, 26) in plan view that covers the nanosheets 23, 25 (24, 26). Therefore, it is possible to reduce a resistance value from the line 52 (54), and thus it is possible to increase the speed of the semiconductor integrated circuit device.

The line 53 is disposed on the upper side in the Y direction in the drawing with respect to the lines 52, 54 (the side on which the nanosheets 25, 26 are not exposed from the gate lines 34, 35, respectively, and which is opposite to the side on which the active region 2N2 is disposed close to the cell frame). The via 70 connects the line 53 and the local line connected to part of the active region 2P2 that serves as the drain of the transistors P11, P12. The via 71 connects the line 53 and the local line connected to part of the active region 2N2 that serves as the drain of the transistor N12. In plan view, the vias 70, 71 are formed on the upper side in the Y direction in the drawing with respect to the lines 52, 54. Accordingly, it is possible to shorten the distance from the line 53 to part of the active region 2P2 that serves as the drain of the transistor P11, P12 and the distance from the line 53 to part of the active region 2N2 that serves as the drain of the transistor N12. Therefore, it is possible to reduce a resistance value from the line 53 to part of the active region 2P2 (2N2) that serves as the drain of the transistor P11, P12 (N12), and thus it is possible to increase the speed of the semiconductor integrated circuit device.

### Configuration of 2-Input NAND Cell C8

The 2-input NAND cell C8 and the 2-input NAND cell C2 have substantially the same configuration. Specifically, the 2-input NAND cell C8 has the P-type transistors P11, P12 and the N-type transistors N11, N12, and forms the NAND circuit with the inputs A, B and the output Y.

As shown in FIG. 7(c) and 7(d), the 2-input NAND cell C8 has an active region 2P8, 2N8 which is different in width in the Y direction from the active region 2P2, 2N2 in the 2-input NAND cell C2 shown in FIG. 7(a) and 7(b).

Specifically, the width of the active region 2P8, 2N8 in the Y direction is w2. The width w2 is smaller than the width w1. That is, the drive capability of the 2-input NAND cell C2 is greater than the drive capability of the 2-input NAND cell C8.

As shown in FIG. 7, the lower end of the active region 2P8 (2N8) in the Y direction in the drawing is disposed at the same position in the Y direction as the lower end of the active region 2P2 (2N2) in the Y direction in the drawing. That is, the lower end of the active region 2P2 (2N2) of the 2-input NAND cell C2 in the Y direction in the drawing and the lower end of the active region 2P8 (2N8) of the 2-input NAND cell C8 in the Y direction in the drawing are aligned in the Y direction. In the 2-input NAND cell C2, C8, the lower surface of the nanosheets 23 (25) in the Y direction in the drawing is exposed from the gate line 34. In the 2-input NAND cell C2, C8, the lower surface of the nanosheet 24 (26) in the Y direction in the drawing is exposed from the gate line 35. That is, in the 2-input NAND cells C2, C8, the positions of the surfaces of the nanosheets exposed from the gate lines are aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

This embodiment employs an exemplary case in which the two 2-input NAND cells of which the active regions are different in width are disposed in the circuit block, but three or more 2-input NAND cells of which the active regions are different in width may be disposed in the circuit block. In this case, in each 2-input NAND cell, the positions of the surfaces of the nanosheets exposed from the gate line only need to be aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

### Configuration of 2-Input NOR Cell C3

As shown in FIG. 8(a), in the BM0 wiring layer, the power supply line 11 extending in the X direction is formed at a lower end portion of the cell in the Y direction in the drawing. The power supply line 11 supplies the power supply voltage VDD.

An active region 2P3 is formed in a P-type transistor region in the cell lower portion. The active region 2P3 overlaps with the power supply line 11 in plan view.

In the active region 2P3, transistors P21, P22 are formed. The transistors P21, P22 have nanosheets 27, 28 extending in the X direction, respectively. Part of the active region 2P3 that serves as the source of the transistor P21, P22 is connected with the power supply line 11 through a via 73. The via 73 is formed in a region in which the power supply line 11 and the active region 2P3 overlap with each other in plan view.

As shown in FIG. 8(b), an active region 2N3 is formed in an N-type transistor region in the cell upper portion. The active region 2N3 overlaps with the active region 2P3 in plan view.

In the active region 2N3, transistors N21, N22 are formed. The transistors N21, N22 have nanosheets 29, 30 extending in the X direction, respectively.

Gate lines 36, 37 extending in the Y direction are formed. The nanosheets 27, 29 overlap with the gate line 36 in plan view. The nanosheets 28, 30 overlap with the gate line 37 in plan view. The gate line 36 corresponds to the gates of the transistors P21, N21. The gate line 37 corresponds to the gates of the transistors P22, N22.

The gate line 36 covers the outer peripheries of the nanosheets 27, 29 in the Y direction and the Z direction so that part of the outer peripheries of the nanosheets 27, 29 is exposed. The gate line 37 covers the outer peripheries of the nanosheets 28, 30 in the Y direction and the Z direction so that part of the outer peripheries of the nanosheets 28, 30 is exposed. Specifically, the surface of the nanosheets 27, 29 that is located on the lower side in the Y direction in the drawing is exposed from the gate line 36, and the surface of the nanosheets 27, 29 that is located on the upper side in the Y direction in the drawing is covered with the gate line 36. The surface of the nanosheets 28, 30 that is located on the lower side in the Y direction in the drawing is exposed from the gate line 37, and the surface of the nanosheets 28, 30 that is located on the upper side in the Y direction in the drawing is covered with the gate line 37.

The power supply line 51 and the lines 52 to 54 extending in the X direction are formed in the M0 wiring layer. The power supply line 51 supplies the power supply voltage VSS. The line 52 corresponds to the input A, the line 53 corresponds to the output Y, and the line 54 corresponds to the input B.

The power supply line 51 is formed at a lower portion of the cell in the Y direction in the drawing. The power supply line 51 overlaps with the active region 2N3 in plan view. Through the vias 74, 75 and the local line, the power supply line 51 is connected with part of the active region 2N3 that serves as the source of the transistors N21, N22. The vias 74, 75 are formed in a region in which the power supply line 51 and the active region 2N3 overlap with each other in plan view.

The line 52 is disposed near a center portion of the cell in the Y direction in the drawing. The line 52 is connected with the gate line 36 through a via 76. The via 76 is formed in a region in which the line 52 and the active region 2N3 overlap with each other in plan view.

The line 53 is disposed in an upper portion of the cell in the Y direction in the drawing. Through vias 77, 78 and the local line, the line 53 is connected with part of the active region 2P3 that serves as the drain of the transistor P22 and part of the active region 2N3 that serves as the drain of the transistor N21, N22.

The line 54 is disposed near a center portion of the cell in the Y direction in the drawing. The line 54 is connected with the gate line 37 through a via 79. The via 79 is formed in a region in which the line 54 and the active region 2N3 overlap with each other in plan view.

As described above, the 2-input NOR cell C3 has the P-type transistors P21, P22 and the N-type transistors N21, N22, and forms the NOR circuit with the inputs A, B and the output Y.

As shown in FIG. 8(a) and 8(b), the active regions 2P3, 2N3 in the 2-input NOR cell C3 has a width w1 in the Y direction in plan view.

In the 2-input NOR cell C3 shown in FIG. 8, the surfaces of the nanosheets 27, 29 that are located on the lower side in the Y direction in the drawing are exposed from the gate line 36. The surfaces of the nanosheets 28, 30 that are located on the lower side in the Y direction in the drawing are exposed from the gate line 37. The cell rows CR are disposed so that they are alternately inverted in the Y direction. That is, the cells adjacent to each other in the Y direction are disposed so that the nanosheets in the active regions face each other in the Y direction while the surfaces exposed from the gate line (the surfaces located on the lower side in the drawing) face each other in the Y direction. Accordingly, it is possible to shorten the distance d3 from the lower end of the active region 2P3 (2N3) in the Y direction in the drawing to the lower end of the cell frame in the Y direction in the drawing. In other words, the active regions 2P3, 2N3 (the nanosheets 27 to 30) can be disposed close to the lower end of the cell frame in the Y direction in the drawing. Therefore, the area of the semiconductor integrated circuit device can be reduced.

The surfaces of the nanosheets 27, 29 that are located on the upper side in the Y direction in the drawing are not exposed from the gate line 36. The surfaces of the nanosheets 28, 30 that are located on the upper side in the Y direction in the drawing are not exposed from the gate line 37. That is, the cells adjacent to each other in the Y direction are disposed so that the nanosheets in the active regions face each other in the Y direction while the surfaces exposed from the gate line (the surfaces located on the lower side in the drawing) face each other in the Y direction, and the surfaces not exposed from the gate line (the surfaces located on the upper side in the drawing) face each other in the Y direction. Thus, the distance d3 from the lower end of the active region 2P3 (2N3) in the Y direction in the drawing to the lower end of the cell frame in the Y direction in the drawing is smaller than the distance d4 from the upper end of the active region 2P3 (2N3) in the Y direction in the drawing to the upper end of the cell frame in the Y direction in the drawing. In other words, in plan view, the active region 2P3 (2N3) is disposed close to the lower end of the cell frame in the drawing with respect to the center of the cell frame in the Y direction in the drawing. That is, in plan view, the center portion of the active region 2P3 (2N3) in the Y direction in the drawing is located on the lower side in the drawing with respect to the center portion of the cell frame in the Y direction in the drawing.

In plan view, the power supply lines 11, 51 are formed at the lower end portion of the cell in the Y direction in the drawing, and are shared with the standard cell disposed on the lower side of the 2-input NOR cell C3 in the Y direction in the drawing. Accordingly, by the 2-input NOR cell C3 being disposed in the circuit block of FIG. 1, the power supply lines for supplying the power supply voltages VDD, VSS can be reinforced. Therefore, it is possible to reduce a decrease in the power supply voltage, and also it is possible to reduce occurrence of electromigration due to current concentration.

The via 73 that connects the power supply line 11 and part of the active region 2P3 that serves as the source of the transistor P21 is formed in a region in which the power supply line 11 and the active region 2P3 overlap with each other in plan view. In plan view, the via 73 is disposed close to the upper side in the drawing in the region in which the power supply line 11 and the active region 2P3 overlap with each other in plan view. In other words, in plan view, the distance d5 in the Y direction from the center portion of the via 73 in the drawing to the upper end of the power supply line 11 in the drawing is smaller than the distance d6 in the Y direction from the center portion of the via 73 in the drawing to the lower end of the active region 2P3 in the drawing. Accordingly, the via 73 is disposed close to the center portion of the active region 2P3 in the Y direction in the drawing, and therefore the difference is reduced between the resistance value from the via 73 to the upper end of the nanosheet 27 of the transistor P21 in the active region 2P3 in the drawing and the resistance value from the via 73 to the lower end of the nanosheet 27 of the transistor P21 in the active region 2P3 in the drawing. Therefore, the current flowing through the transistor P21 is equalized in the Y direction, or in the up-down direction in the drawing, and thus it is possible to increase the speed of the semiconductor integrated circuit device.

The via 74 (75) that connects the power supply line 51 and part of the active region 2N3 that serves as the source of the transistor N21 (N22) is formed in a region in which the power supply line 51 and the active region 2N3 overlap with each other in plan view. In plan view, the via 74 (75) is disposed close to the upper side in the drawing in the region in which the power supply line 51 and the active region 2N3 overlap with each other in plan view. In other words, in plan view, the distance d5 in the Y direction from the center portion of the via 74 (75) in the drawing to the upper end of the power supply line 51 in the drawing is smaller than the distance d6 in the Y direction from the center portion of the via 74 (75) in the drawing to the lower end of the active region 2N3 in the drawing. Accordingly, the via 74 (75) is disposed close to the center portion of the active region 2N3 in the Y direction in the drawing, and therefore the difference is reduced between the resistance value from the via 74 (75) to the upper end of the nanosheet 29 (30) of the transistor N21 (N22) in the active region 2N3 in the drawing and the resistance value from the via 74 (75) to the lower end of the nanosheet 29 (30) of the transistor N21 (N22) in the active region 2N3 in the drawing. Therefore, the current flowing through the transistor N21 (N22) is equalized in the Y direction, or in the up-down direction in the drawing, and thus it is possible to increase the speed of the semiconductor integrated circuit device.

The via 76 (79) that connects the line 52 (54) and the gate line 36 (37) is formed in a region to overlap with the active region 2N3 and the gate line 36 (37) in plan view. Accordingly, it is possible to shorten the distance from the line 52 (54) (the input A (the input B)) to part of the gate line 36 (37) overlapping with the nanosheets 27, 29 (28, 30) in plan view that covers the nanosheets 27, 29 (28, 30). Therefore, it is possible to reduce a resistance value from the line 52 (54), and thus it is possible to increase the speed of the semiconductor integrated circuit device.

The line 53 is disposed on the upper side in the Y direction in the drawing with respect to the lines 52, 54 (the side on which the nanosheets 29, 30 are not exposed from the gate lines 36, 37 and which is opposite to the side on which the active region 2N3 is disposed close to the cell frame). The via 77 connects the line 53 and the local line connected to part of the active region 2P3 that serves as the drain of the transistor P22. The via 78 connects the line 53 and the local line connected to part of the active region 2N3 that serves as the drain of the transistors N21, N22. In plan view, the vias 77, 78 are formed on the upper side in the Y direction in the drawing with respect to the lines 52, 54. Accordingly, it is possible to shorten the distance from the line 53 to part of the active region 2P3 that serves as the drain of the transistor P22 and the distance from the line 53 to part of the active region 2N3 that serves as the drain of the transistor N21, N22. Therefore, it is possible to reduce a resistance value from the line 53 to part of the active region 2P3 (2N3) that serves as the drain of the transistor P22 (N21, N22), and thus it is possible to increase the speed of the semiconductor integrated circuit device.

### Configuration of 2-Input NOR Cell C9

The 2-input NOR cell C9 and the 2-input NOR cell C3 have substantially the same configuration. Specifically, the 2-input NOR cell C9 has the P-type transistors P21, P22 and the N-type transistors N21, N22, and forms a NOR circuit with the inputs A, B and the output Y.

As shown in FIG. 8(c) and 8(d), the 2-input NOR cell C9 has an active region 2P9, 2N9 which is different in width in the Y direction from the active region 2P3, 2N3 in the 2-input NOR cell C3 shown in FIG. 8(a) and 8(b).

Specifically, the width of the active region 2P9, 2N9 in the Y direction is w2. The width w2 is smaller than the width w1. That is, the drive capability of the 2-input NOR cell C3 is greater than the drive capability of the 2-input NOR cell C9.

As shown in FIG. 8, the lower end of the active region 2P9 (2N9) in the Y direction in the drawing is disposed at the same position in the Y direction as the lower end of the active region 2P3 (2N3) in the Y direction in the drawing. That is, the lower end of the active region 2P3 (2N3) of the 2-input NOR cell C3 in the Y direction in the drawing and the lower end of the active region 2P9 (2N9) of the 2-input NOR cell C9 in the Y direction in the drawing are aligned in the Y direction. In the 2-input NOR cell C3, C9, the lower surface of the nanosheet 27 (29) in the Y direction in the drawing is exposed from the gate line 36. In the 2-input NOR cell C3, C9, the lower surface of the nanosheets 28 (30) in the Y direction in the drawing is exposed from the gate line 37. That is, in the 2-input NOR cells C3, C9, the positions of the surfaces of the nanosheets exposed from the gate lines are aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

This embodiment employs an exemplary case in which the two 2-input NOR cells of which the active regions are different in width are disposed in the circuit block, but three or more 2-input NOR cells of which the active regions are different in width may be disposed in the circuit block. In this case, in each 2-input NOR cell, the positions of the surfaces of the nanosheets exposed from the gate line only need to be aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

### Second Embodiment

### Configuration of Circuit Block

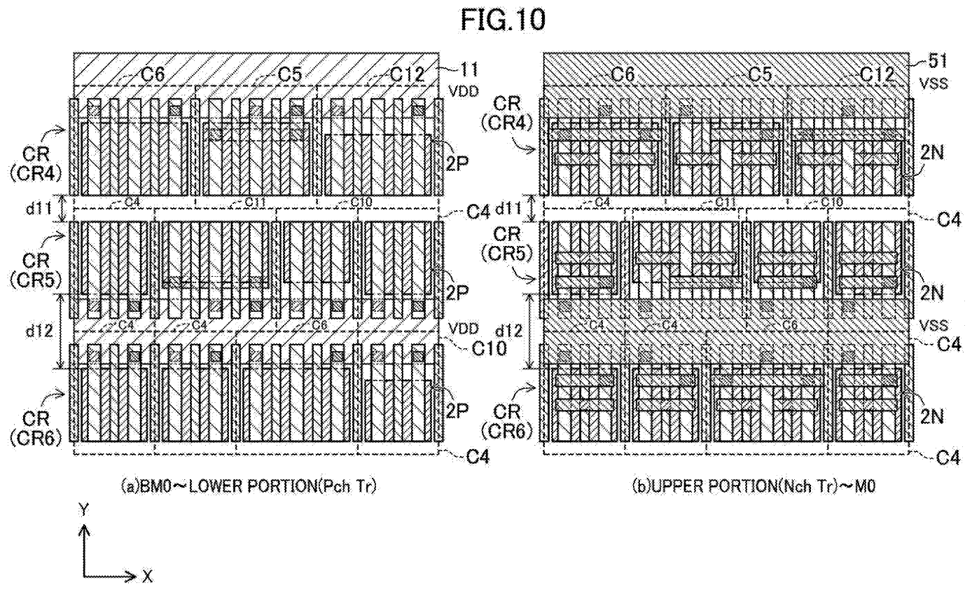

FIG. 10 is a plan view showing an example of the layout of a circuit block in the semiconductor integrated circuit device according to a second embodiment. Specifically, FIG. 10(a) shows a cell lower part, and FIG. 10(b) shows a cell upper part.

The block layout of FIG. 10 is formed by disposing the standard cells. Also in this embodiment, a power supply line is formed in the BM0 wiring layer, which is a back wiring layer provided on the back surface of a semiconductor chip on which a transistor is formed, and a M0 wiring layer, which is a metal wiring layer above the transistor.

In the layout of FIG. 10, a plurality of cells arranged in the X direction form cell rows CR (CR4 to CR6). The plurality of cell rows CR (three rows in FIG. 10) are arranged in the Y direction. The plurality of cells include cells having logic functions, such as an inverter, a NAND gate, and a NOR gate. For example, the plurality of cells include inverter cells C4, C10; 2-input NAND cells C5, C11; 2-input NOR cells C6, C12; and the like, each described later.

In each cell, power supply lines are formed in the BM0 wiring layer and the M0 wiring layer. Specifically, a power supply line (a power supply line 11) for supplying a power supply voltage VDD is formed in the BM0 wiring layer, and a power supply line (a power supply line 51) for supplying a power supply voltage VSS is formed in the M0 wiring layer. Each cell is supplied with the power supply voltages VDD, VSS from the outside through these power supply lines. The cell rows CR are disposed so that they are alternately inverted in the Y direction.

In the cell row CR4, CR 6, a power supply line 11 (51) is formed at an upper end portion in the Y direction in the drawing. In the cell row CR5, a power supply line 11 (51) is formed at a lower end portion in the Y direction in the drawing. At a cell boundary, the cell rows CR5, CR6 adjacent to each other in the Y direction share the power supply line 11 (51) continuous in the X direction. That is, in the block layout of FIG. 10, the cell rows CR adjacent to each other in the Y direction share the power supply line formed at the cell boundary. Since the cell rows CR adjacent to each other in the Y direction share the power supply line, the power supply line is reinforced. Therefore, it is possible to reduce a decrease in the power supply voltage, and also it is possible to reduce occurrence of electromigration due to current concentration.

An active region 2P that forms the channel, source, and drain of a P-type transistor is formed in the lower portion of each cell. An active region 2N that forms the channel, source, and drain of an N-type transistor is formed in the upper portion of each cell. In the cell row CR, the active regions 2P are aligned in the X direction, and the active regions 2N are aligned in the X direction.

Although the details will be described later, in the standard cell disposed in the cell row CR4, the active region 2P (2N) contains a nanosheet of which the surface located on the upper side in the Y direction in the drawing is not exposed from a gate line, and the surface located on the lower side in the Y direction in the drawing is exposed from a gate line. In the standard cell disposed in the cell row CR5, the active region 2P (2N) contains a nanosheet of which the surface located on the upper side in the Y direction in the drawing is exposed from a gate line, and the surface located on the lower side in the Y direction in the drawing is not exposed from a gate line. In the standard cell disposed in the cell row CR6, the active region 2P (2N) contains a nanosheet of which the surface located on the upper side in the Y direction in the drawing is not exposed from a gate line, and the surface located on the lower side in the Y direction in the drawing is exposed from a gate line. That is, in the block layout of FIG. 10, the cells adjacent to each other in the Y direction are disposed so that the nanosheets in the active regions face each other in the Y direction while the surfaces exposed from the gate line face each other in the Y direction and the surfaces not exposed from the gate line face each other in the Y direction. Specifically, the nanosheet in the active region 2P (2N) of the standard cell disposed in the cell row CR4 and the nanosheet in the active region 2P (2N) of the standard cell disposed in the cell row CR5 are disposed so that the surfaces facing each other in the Y direction are exposed from the gate line. The nanosheet in the active region 2P (2N) of the standard cell disposed in the cell row CR5 and the nanosheet in the active region 2P (2N) of the standard cell disposed in the cell row CR6 are disposed so that the surfaces facing each other in the Y direction are not exposed from the gate line. Accordingly, it is possible to shorten the distance d11 between the active region 2P (2N) of the standard cell disposed in the cell row CR4 and the active region 2P (2N) of the standard cell disposed in the cell row CR5, and therefore it is possible to reduce the area of the semiconductor integrated circuit device. In other words, the distance d11 between the active region 2P (2N) of the standard cell disposed in the cell row CR4 and the active region 2P (2N) of the standard cell disposed in the cell row CR5 is smaller than the distance d12 between the active region 2P (2N) of the standard cell disposed in the cell row CR5 and the active region 2P (2N) of the standard cell disposed in the cell row CR6.

The standard cells disposed in the cell row CR4 are disposed so that in the active region 2P (2N), the lower ends located on the lower side in the drawing are disposed at the same position in the Y direction. The standard cells disposed in the cell row CR5 are disposed so that in the active region 2P (2N), the upper ends located on the upper side in the drawing are disposed at the same position in the Y direction. The standard cells disposed in the cell row CR6 are disposed so that in the active region 2P (2N), the lower ends located on the lower side in the drawing are disposed at the same position in the Y direction. That is, in the cell row CR4, the lower ends of the active regions 2P (2N) that are located on the lower side in the Y direction in the drawing are aligned. In the cell row CR5, the upper ends of the active regions 2P (2N) that are located on the upper side in the Y direction in the drawing are aligned. In the cell row CR6, the lower ends of the active regions 2P (2N) that are located on the lower side in the Y direction in the drawing are aligned. In the standard cell disposed in the cell row CR4, the active region 2P (2N) contains the nanosheet of which the surface located on the lower side in the Y direction in the drawing is exposed from the gate line. In the standard cell disposed in the cell row CR5, the active region 2P (2N) contains the nanosheet of which the surface located on the upper side in the Y direction in the drawing is exposed from the gate line. In the standard cell disposed in the cell row CR6, the active region 2P (2N) contains the nanosheet of which the surface located on the lower side in the Y direction in the drawing is exposed from the gate line. That is, the standard cells disposed in the cell row CR4 are disposed so that the positions of the surfaces of the nanosheets that are exposed from the gate line are aligned in the Y direction. The standard cells disposed in the cell row CR5 are disposed so that the positions of the surfaces of the nanosheets that are exposed from the gate line are aligned in the Y direction. The standard cells disposed in the cell row CR6 are disposed so that the positions of the surfaces of the nanosheets that are exposed from the gate line are aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

### Configuration of Inverter Cell C4

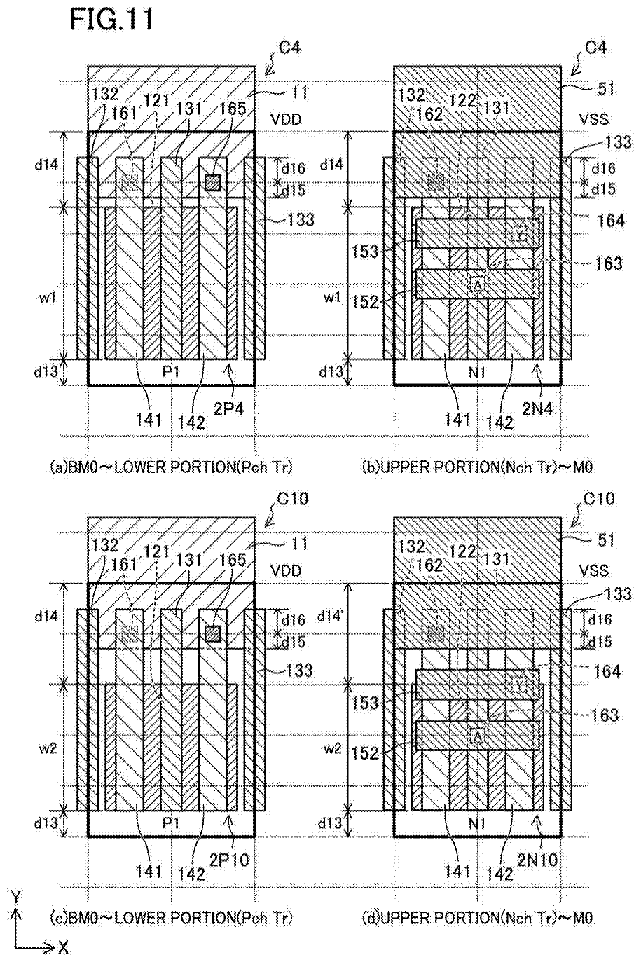

FIG. 11 is plan view showing an example of the layout structure of the inverter cell according to the second embodiment. Specifically, FIG. 11(a) shows a cell lower portion of the inverter cell C4; FIG. 11(b) shows a cell upper portion of the inverter cell C4; FIG. 11(c) shows a cell lower portion of the inverter cell C10; and FIG. 11(d) shows a cell upper portion of the inverter cell C10. Each of the inverter cells C4, C10 of FIG. 11 forms the inverter circuit of FIG. 4.

As shown in FIG. 11(a), in the BM0 wiring layer, the power supply line 11 extending in the X direction is formed at an upper end portion of the cell in the Y direction in the drawing. The power supply line 11 supplies the power supply voltage VDD.

An active region 2P4 is formed in a P-type transistor region in the cell lower portion. In the active region 2P4, a transistor P1 is formed. The transistor P1 has a nanosheet 121.

As shown in FIG. 11(b), an active region 2N4 is formed in an N-type transistor region in the cell upper portion. The active region 2N4 is disposed above the active region 2P4 in the Z direction. The active region 2N4 overlaps with the active region 2P4 in plan view.

In the active region 2N4, an N-type transistor N1 is formed. The transistor N1 has a nanosheet 122.

At the center portion of the cell in the X direction in the drawing, a gate line 131 extending in the Y direction is formed. The nanosheets 121, 122 overlap with the gate line 131 in plan view. The gate line 131 corresponds to the gates of the transistors P1, N1.

The gate line 131 covers the outer peripheries of the nanosheets 121, 122 in the Y direction and the Z direction so that part of the outer peripheries of the nanosheets 121, 122 is exposed. Specifically, the surface of each of the nanosheets 121, 122 that is located on the lower side in the Y direction in the drawing is exposed from the gate line 131, and the surface of each of the nanosheets 121, 122 that is located on the upper side in the Y direction in the drawing is covered with the gate line 131.

Dummy gate lines 132, 133 extending in the Y direction and the Z direction are formed on the cell frame on both sides in the X direction. The dummy gate line 132 is shared with other cells disposed on the left side in the drawing. The dummy gate line 133 is shared with other cells disposed on the right side in the drawing.

As shown in FIG. 11(a), local lines 141, 142 extending in the Y direction are formed in the cell lower portion. The local line 141 is connected with part of the active region 2P4 that serves as the source of the transistor P1. The local line 141 is connected with the power supply line 11 through a via 161. The via 161 is formed in a region in which the local line 141 and the power supply line 11 overlap with each other in plan view. That is, through the via 161 and the local line 141, the power supply line 11 is connected with part of the active region 2P4 that serves as the source of the transistor P1. The local line 142 is connected with part of the active region 2P4 that serves as the drain of the transistor P1.

As shown in FIG. 11(b), local lines 143, 144 extending in the Y direction are formed in the cell upper portion. The local line 143 is connected with part of the active region 2N4 that serves as the source of the transistor N1. The local line 144 is connected with part of the active region 2N4 that serves as the drain of the transistor N1.

The power supply line 51 and the lines 52, 53 extending in the X direction are formed in the M0 wiring layer. The power supply line 51 supplies the power supply voltage VSS. The line 52 corresponds to the input A, and the line 53 corresponds to the output Y.

The power supply line 51 is formed at an upper end portion of the cell in the Y direction in the drawing. Through the via 162 and the local line 143, the power supply line 51 is connected with part of the active region 2N4 that serves as the source of the transistor N1. The via 162 is formed in a region in which the power supply line 51 and the local line 143 overlap with each other in plan view.

The line 52 is disposed near the center portion of the cell in the Y direction in the drawing. The line 52 is connected with the gate line 131 through a via 163. The via 163 is formed in a region in which the line 52 and the active region 2N4 overlap with each other in plan view.

The line 53 is disposed between the power supply line 51 and the line 52 in plan view. Through vias 164, 165 and the local lines 142, 144, the line 53 is connected with a portion that serves as the drain of the transistor P1 and a portion that serves as the drain of the transistor N1.

As described above, the inverter cell C4 has the P-type transistor P1 and the N-type transistor N1, and forms the inverter circuit with the input A and the output Y.

As shown in FIG. 11(a) and 11(b), the active region 2P4, 2N4 in the inverter cell C4 has a width w1 in the Y direction in plan view.

In the inverter cell C4 shown in FIG. 11, the surfaces of the nanosheets 121, 122 that are located on the lower side in the Y direction in the drawing are exposed from the gate line 131. The cell rows CR are disposed so that they are alternately inverted in the Y direction. That is, the cells adjacent to each other in the Y direction are disposed so that the nanosheets in the active regions face each other in the Y direction while the surfaces exposed from the gate line (the surfaces located on the lower side in the drawing) face each other in the Y direction. Accordingly, it is possible to shorten the distance d13 from the lower end of the active region 2P4 (2N4) in the Y direction in the drawing to the lower end of the cell frame in the Y direction in the drawing. In other words, the active regions 2P4, 2N4 (the nanosheets 121, 122) can be disposed close to the lower end of the cell frame in the Y direction in the drawing. Therefore, the area of the semiconductor integrated circuit device can be reduced.

The surfaces of the nanosheets 121, 122 that are located on the upper side in the Y direction in the drawing are not exposed from the gate line 131. That is, the cells adjacent to each other in the Y direction are disposed so that the nanosheets in the active regions face each other in the Y direction while the surfaces exposed from the gate line (the surfaces located on the lower side in the drawing) face each other in the Y direction, and the surfaces not exposed from the gate line (the surfaces located on the upper side in the drawing) face each other in the Y direction. Thus, the distance d13 from the lower end of the active region 2P4 (2N4) in the Y direction in the drawing to the lower end of the cell frame in the Y direction in the drawing is smaller than the distance d14 from the upper end of the active region 2P4 (2N4) in the Y direction in the drawing to the upper end of the cell frame in the Y direction in the drawing. In other words, in plan view, the active region 2P4 (2N4) is disposed close to the lower end of the cell frame in the drawing with respect to the center of the cell frame in the Y direction in the drawing. That is, in plan view, the center portion of the active region 2P4 (2N4) in the Y direction in the drawing is located on the lower side in the drawing with respect to the center portion of the cell frame in the Y direction in the drawing.

In plan view, the power supply lines 11, 51 are formed at the upper end portion of the cell in the Y direction in the drawing, and are shared with the standard cell disposed on the upper side of the inverter cell C4 in the Y direction in the drawing. Accordingly, by the inverter cell C4 being disposed in the circuit block of FIG. 10, the power supply lines for supplying the power supply voltages VDD, VSS can be reinforced. Therefore, it is possible to reduce a decrease in the power supply voltage, and also it is possible to reduce occurrence of electromigration due to current concentration.

The power supply line 11 (51) does not overlap with the active region 2P4 (2N4) in plan view. Accordingly, it is possible to reduce the load capacitance by the power supply line 11 (51) that supplies the power supply voltage VDD (VSS) to the transistor P1 (N1) formed in the active region 2P4 (2N4), and therefore it is possible to increase the speed of the semiconductor integrated circuit device. The power supply line 11 (51) may overlap with the active region 2P4 (2N4) in plan view. In this case, the region in which the power supply line 11 (51) and the active region 2P4 (2N4) overlap with each other can be made smaller than the inverter cell C1 of FIG. 2, and therefore it is possible to increase the speed of the semiconductor integrated circuit device.

The via 163 that connects the line 52 and the gate line 131 is formed in a region to overlap with the active region 2N4 and the gate line 131 in plan view. Accordingly, it is possible to shorten the distance from the line 52 (the input A) to part of the gate line 131 overlapping with the nanosheets 121, 122 in plan view that covers the nanosheets 21, 22. Therefore, it is possible to reduce a resistance value from the line 52, and thus it is possible to increase the speed of the semiconductor integrated circuit device.

The line 53 is disposed on the upper side in the Y direction in the drawing with respect to the line 52 (the side on which the nanosheet 122 is not exposed from the gate line 131 and which is opposite to the side on which the active region 2N4 is disposed close to the cell frame). The via 164 that connects the line 53 and the local line 144 and the via 165 that connects the local lines 142, 144 are formed on the upper side in the Y direction in the drawing in plan view with respect to the line 52. Accordingly, it is possible to shorten the distance from the line 53 to part of the active region 2P4 that serves as the drain of the transistor P1 and the distance from the line 53 to part of the active region 2N4 that serves as the drain of the transistor N1. Therefore, it is possible to reduce a resistance value from the line 53 to part of the active region 2P4 (2N4) that serves as the drain of the transistor P1 (N1), and thus it is possible to increase the speed of the semiconductor integrated circuit device.

The via 161 that connects the power supply line 11 and the local line 141 connected with part of the active region 2P4 that serves as the source of the transistor P1 is formed in a region in which the power supply line 11 and the local line 141 overlap with each other in plan view. In plan view, the via 161 is disposed close to the lower side in the drawing in the region in which the power supply line 11 and the local line 141 overlap with each other in plan view. In other words, in plan view, the distance d15 in the Y direction from a center portion of the via 161 in the drawing to the lower end of the power supply line 11 in the drawing is smaller than the distance d16 in the Y direction from the center portion of the via 161 in the drawing to the upper end of the local line 141 in the drawing. Accordingly, the via 161 is disposed even closer to the active region 2P4. Therefore, it is possible to reduce a resistance value from the via 161 to the nanosheet 121, and thus it is possible to increase the speed of the semiconductor integrated circuit device.

The via 162 that connects the power supply line 51 and the local line 143 connected with part of the active region 2N4 that serves as the source of the transistor N1 is formed in a region in which the power supply line 11 and the local line 143 overlap with each other in plan view. In plan view, the via 162 is disposed close to the lower side in the drawing in the region in which the power supply line 51 and the local line 143 overlap with each other in plan view. In other words, in plan view, the distance d15 in the Y direction from a center portion of the via 162 in the drawing to the lower end of the power supply line 51 in the drawing is smaller than the distance d16 in the Y direction from the center portion of the via 162 in the drawing to the upper end of the local line 143 in the drawing. Accordingly, the via 162 is disposed even closer to the active region 2N4. Therefore, it is possible to reduce a resistance value from the via 162 to the nanosheet 122, and thus it is possible to increase the speed of the semiconductor integrated circuit device.

### Configuration of Inverter Cell C10

The inverter cell C10 and the inverter cell C4 have substantially the same configuration. Specifically, the inverter cell C10 has the P-type transistor P1 and the N-type transistor N1, and forms the inverter circuit with the input A and the output Y.

As shown in FIG. 11(c) and 11(d), the inverter cell C10 has an active region 2P10, 2N10 which is different in width in the Y direction from the active region 2P4, 2N4 in the inverter cell C4 shown in FIG. 11(a) and 11(b).

Specifically, the width of the active region 2P10, 2N10 in the Y direction is w2. The width w2 is smaller than the width w1. That is, the drive capability of the inverter cell C4 is greater than the drive capability of the inverter cell C10.

As shown in FIG. 11, the lower end of the active region 2P10 (2N10) in the Y direction in the drawing is disposed at the same position in the Y direction as the lower end of the active region 2P4 (2N4) in the Y direction in the drawing. That is, the lower end of the active region 2P4 (2N4) of the inverter cell C4 in the Y direction in the drawing and the lower end of the active region 2P10 (2N10) of the inverter cell C10 in the Y direction in the drawing are aligned in the Y direction. In the inverter cells C4, C10, the surface of the nanosheet 121 (122) that is located on the lower side in the Y direction in the drawing is exposed from the gate line 131. That is, in the inverter cells C4, C10, the positions of the surfaces of the nanosheets exposed from the gate lines are aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

This embodiment employs an exemplary case in which the two inverter cells of which the active regions are different in width are disposed in the circuit block, but three or more inverter cells of which the active regions are different in width may be disposed in the circuit block. In this case, in each inverter cell, the positions of the surfaces of the nanosheets exposed from the gate line only need to be aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

### Other Layout Structures of Standard Cell

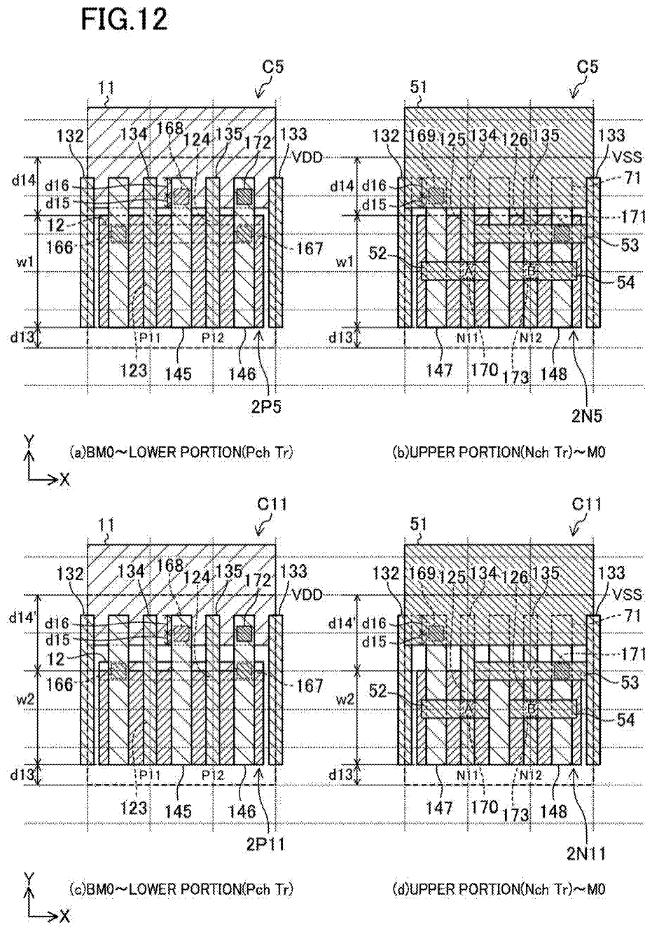

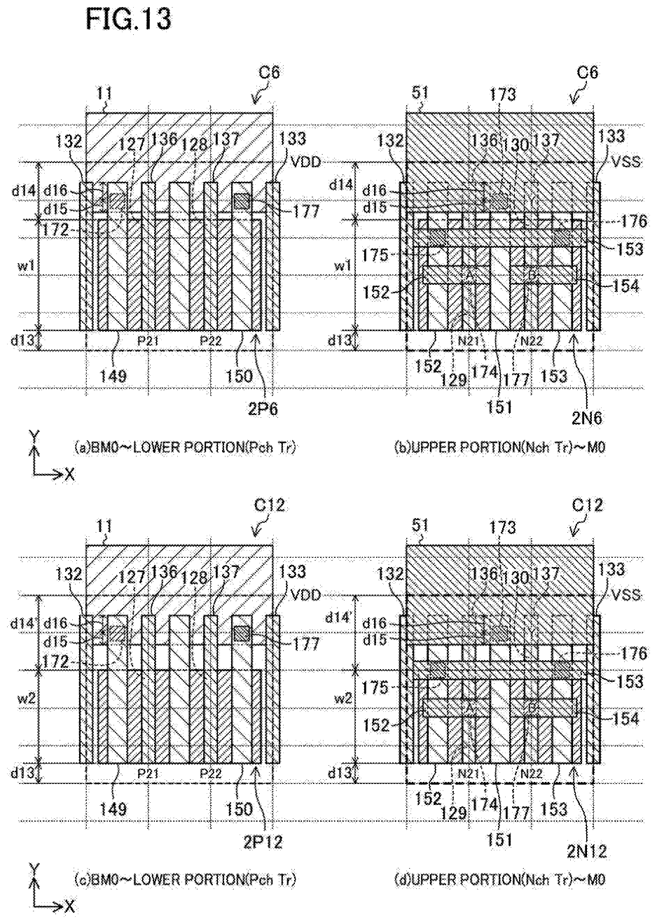

FIGS. 12 and 13 are plan views showing examples of the layout structure of the cell contained in the semiconductor integrated circuit device of the second embodiment. FIG. 12(a) is a cell lower portion of the 2-input NAND cell C5. FIG. 12(b) is a cell upper portion of the 2-input NAND cell C5. FIG. 12(c) is a cell lower portion of the 2-input NAND cell C11. FIG. 12(d) is a cell upper portion of the 2-input NAND cell C11. FIG. 13(a) is a cell lower portion of the 2-input NOR cell C6. FIG. 13(b) is a cell upper portion of the 2-input NOR cell C6. FIG. 13(c) is a cell lower portion of the 2-input NOR cell C12. FIG. 13(d) is a cell upper portion of the 2-input NOR cell C12. The 2-input NAND cells C5, C11 of FIG. 12 form the 2-input NAND circuit of FIG. 9(a), and the 2-input NOR cells C6, C12 of FIG. 13 form the 2-input NOR circuit of FIG. 9(b).

The layout structures of FIGS. 12 and 13 can be easily understood from the above description of the inverter cell of FIG. 11 and the circuit diagrams of FIG. 9, and therefore, the description thereof will be omitted.

Configuration of 2-input NAND Cell C5

As shown in FIG. 12(a), in the BM0 wiring layer, the power supply line 11 extending in the X direction is formed at an upper end portion of the cell in the Y direction in the drawing. The power supply line 11 supplies the power supply voltage VDD.

An active region 2P5 is formed in a P-type transistor region in the cell lower portion. In the active region 2P5, transistors P11, P12 are formed. The transistors P11, P12 have nanosheets 123, 124 extending in the X direction, respectively.

Part of the active region 2P5 that serves as the drain of the transistor P11, P12 is connected through vias 166, 167 and a line 12. The line 12 is formed in the BM0 wiring layer.

As shown in FIG. 12(b), an active region 2N5 is formed in an N-type transistor region in the cell upper portion. The active region 2N5 overlaps with the active region 2P5 in plan view.

In the active region 2N5, transistors N11, N12 are formed. The transistors N11, N12 have nanosheets 125, 126 extending in the X direction, respectively.

Gate lines 134, 135 extending in the Y direction are formed. The nanosheets 123, 125 overlap with the gate line 134 in plan view. The nanosheets 124, 126 overlap with the gate line 135 in plan view. The gate line 134 corresponds to the gates of the transistors P11, N11. The gate line 135 corresponds to the gates of the transistors P12, N12.

The gate line 134 covers the outer peripheries of the nanosheets 123, 125 in the Y direction and the Z direction so that part of the outer peripheries of the nanosheets 123, 125 is exposed. The gate line 135 covers the outer peripheries of the nanosheets 124, 126 in the Y direction and the Z direction so that part of the outer peripheries of the nanosheets 124, 126 is exposed. Specifically, the surfaces of the nanosheets 123, 125 that are located on the lower side in the Y direction in the drawing are exposed from the gate line 134, and the surfaces of the nanosheets 123, 125 that are located on the upper side in the Y direction in the drawing are covered with the gate line 134. The surfaces of the nanosheets 124, 126 that are located on the lower side in the Y direction in the drawing are exposed from the gate line 135, and the surfaces of the nanosheets 124, 126 that are located on the upper side in the Y direction in the drawing are covered with the gate line 135.

As shown in FIG. 12(a), local lines 145, 146 extending in the Y direction are formed in the cell lower portion. The local line 145 is connected with part of the active region 2P5 that serves as the source of the transistor P11, P12. The local line 145 is connected with the power supply line 11 through a via 168. The via 168 is formed in a region in which the power supply line 11 and the local line 145 overlap with each other in plan view. That is, through the via 168 and the local line 145, the power supply line 11 is connected with part of the active region 2P5 that serves as the source of the transistor P11, P12. The local line 146 is connected with part of the active region 2P5 that serves as the drain of the transistor P12.

As shown in FIG. 12(b), local lines 147, 148 extending in the Y direction are formed in the cell upper portion. The local line 147 is connected with part of the active region 2N5 that serves as the source of the transistor N11. The local line 148 is connected with part of the active region 2N5 that serves as the drain of the transistor N12.

The power supply line 51 and the lines 52 to 54 extending in the X direction are formed in the M0 wiring layer. The power supply line 51 supplies the power supply voltage VSS. The line 52 corresponds to the input A, the line 53 corresponds to the output Y, and the line 54 corresponds to the input B.

The power supply line 51 is formed at an upper end portion of the cell in the Y direction in the drawing. Through the via 169 and the local line 147, the power supply line 51 is connected with part of the active region 2N5 that serves as the source of the transistor N11. The via 169 is formed in a region in which the power supply line 51 and the local line 147 overlap with each other in plan view.

The line 52 is disposed near a center portion of the cell in the Y direction in the drawing. The line 52 is connected with the gate line 134 through a via 170. The via 170 is formed in a region in which the line 52 and the active region 2N5 overlap with each other in plan view.

The line 53 is disposed between the power supply line 51 and the lines 52, 54 in plan view. Through the line 12, the vias 166, 167, 171, 172, and the local line 146, 148, the line 53 is connected with part of the active region 2P5 that serves as the drain of the transistors P11, P12 and part of the active region 2N5 that serves as the drain of the transistor N12.

The line 54 is disposed near a center portion of the cell in the Y direction in the drawing. The line 54 is connected with the gate line 135 through a via 173. The via 173 is formed in a region in which the line 54 and the active region 2N5 overlap with each other in plan view.

As described above, the 2-input NAND cell C5 has the P-type transistors P11, P12 and the N-type transistors N11, N12, and forms the NAND circuit with the inputs A, B and the output Y.

As shown in FIG. 12(a) and 12(b), the active region 2P5, 2N5 in the 2-input NAND cell C2 has a width w1 in the Y direction in plan view.

In the 2-input NAND cell C5 shown in FIG. 12, the surfaces of the nanosheets 123, 125 that are located on the lower side in the Y direction in the drawing are exposed from the gate line 134. The surfaces of the nanosheets 124, 126 that are located on the lower side in the Y direction in the drawing are exposed from the gate line 135. The cell rows CR are disposed so that they are alternately inverted in the Y direction. That is, the cells adjacent to each other in the Y direction are disposed so that the nanosheets in the active regions face each other in the Y direction while the surfaces exposed from the gate line (the surfaces located on the lower side in the drawing) face each other in the Y direction. Accordingly, it is possible to shorten the distance d13 from the lower end of the active region 2P5 (2N5) in the Y direction in the drawing to the lower end of the cell frame in the Y direction in the drawing. In other words, the active regions 2P5, 2N5 (the nanosheets 123 to 126) can be disposed close to the lower end of the cell frame in the Y direction in the drawing. Therefore, the area of the semiconductor integrated circuit device can be reduced.

The surfaces of the nanosheets 123, 125 that are located on the upper side in the Y direction in the drawing are not exposed from the gate line 134. The surfaces of the nanosheets 124, 126 that are located on the upper side in the Y direction in the drawing are not exposed from the gate line 135. That is, the cells adjacent to each other in the Y direction are disposed so that the nanosheets in the active regions face each other in the Y direction while the surfaces exposed from the gate line (the surfaces located on the lower side in the drawing) face each other in the Y direction, and the surfaces not exposed from the gate line (the surfaces located on the upper side in the drawing) face each other in the Y direction. Thus, the distance d13 from the lower end of the active region 2P5 (2N5) in the Y direction in the drawing to the lower end of the cell frame in the Y direction in the drawing is smaller than the distance d14 from the upper end of the active region 2P5 (2N5) in the Y direction in the drawing to the upper end of the cell frame in the Y direction in the drawing. In other words, in plan view, the active region 2P5 (2N5) is disposed close to the lower end of the cell frame in the drawing with respect to the center of the cell frame in the Y direction in the drawing. That is, in plan view, the center portion of the active region 2P5 (2N5) in the Y direction in the drawing is located on the lower side in the drawing with respect to the center portion of the cell frame in the Y direction in the drawing.

In plan view, the power supply lines 11, 51 are formed at the upper end portion of the cell in the Y direction in the drawing, and are shared with the standard cell disposed on the upper side of the 2-input NAND cell C5 in the Y direction in the drawing. Accordingly, by the 2-input NAND cell C5 being disposed in the circuit block of FIG. 10, the power supply lines for supplying the power supply voltages VDD, VSS can be reinforced. Therefore, it is possible to reduce a decrease in the power supply voltage, and also it is possible to reduce occurrence of electromigration due to current concentration.

The power supply line 11 (51) does not overlap with the active region 2P5 (2N5) in plan view. Accordingly, it is possible to reduce the load capacitance by the power supply line 11 (51) that supplies the power supply voltage VDD (VSS) to the transistors P11, P12 (N11, N12) formed in the active region 2P5 (2N5), and therefore it is possible to increase the speed of the semiconductor integrated circuit device. The power supply line 11 (51) may overlap with the active region 2P5 (2N5) in plan view. In this case, the region in which the power supply line 11 (51) and the active region 2P5 (2N5) overlap with each other can be made smaller than the 2-input NAND cell C2 of FIG. 7, and therefore it is possible to increase the speed of the semiconductor integrated circuit device.

The via 170 (173) that connects the line 52 (54) and the gate line 134(135 ) is formed in a region to overlap with the active region 2N5 and the gate line 134(135 ) in plan view. Accordingly, it is possible to shorten the distance from the line 52 (54) (the input A (the input B)) to part of the gate line 134(135 ) overlapping with the nanosheets 123, 125 (124, 126) in plan view that covers the nanosheets 123, 125 (124, 126). Therefore, it is possible to reduce a resistance value from the line 52 (54), and thus it is possible to increase the speed of the semiconductor integrated circuit device.

The line 53 is disposed on the upper side in the Y direction in the drawing with respect to the lines 52, 54 (the side on which the nanosheets 125, 126 are not exposed from the gate lines 134, 135 and which is opposite to the side on which the active region 2N5 is disposed close to the cell frame). The via 171 connects the line 53 and the local line 148 connected to part of the active region 2N5 that serves as the drain of the transistor N12. The via 172 connects the line 148 and the local line 146 connected to part of the active region 2P5 that serves as the drain of the transistor P12. Part of the active region 2P5 that serves as the drain of the transistor P11, P12 is connected through vias 166, 167 and a line 12. In plan view, the vias 166, 167, 171, 172 are formed on the upper side in the Y direction in the drawing with respect to the lines 52, 54. Accordingly, it is possible to shorten the distance from the line 53 to part of the active region 2P5 that serves as the drain of the transistor P11, P12 and the distance from the line 53 to part of the active region 2N5 that serves as the drain of the transistor N12. Therefore, it is possible to reduce a resistance value from the line 53 to part of the active region 2P5 (2N5) that serves as the drain of the transistor P11, P12 (N12), and thus it is possible to increase the speed of the semiconductor integrated circuit device.

The via 168 that connects the power supply line 11 and the local line 145 connected with part of the active region 2P5 that serves as the source of the transistors P11, P12 is formed in a region in which the power supply line 11 and the local line 145 overlap with each other in plan view. In plan view, the via 168 is disposed close to the lower side in the drawing in the region in which the power supply line 11 and the local line 145 overlap with each other in plan view. In other words, in plan view, the distance d15 in the Y direction from a center portion of the via 168 in the drawing to the lower end of the power supply line 11 in the drawing is smaller than the distance d16 in the Y direction from the center portion of the via 168 in the drawing to the upper end of the local line 145 in the drawing. Accordingly, the via 168 is disposed even closer to the active region 2P5. Therefore, it is possible to reduce a resistance value from the via 168 to the nanosheet 123, 124, and thus it is possible to increase the speed of the semiconductor integrated circuit device.

The via 169 that connects the power supply line 51 and the local line 147 connected with part of the active region 2N5 that serves as the source of the transistor N11 is formed in a region in which the power supply line 51 and the local line 147 overlap with each other in plan view. In plan view, the via 169 is disposed close to the lower side in the drawing in the region in which the power supply line 51 and the local line 147 overlap with each other in plan view. In other words, in plan view, the distance d15 in the Y direction from a center portion of the via 169 in the drawing to the lower end of the power supply line 51 in the drawing is smaller than the distance d16 in the Y direction from the center portion of the via 169 in the drawing to the upper end of the local line 147 in the drawing. Accordingly, the via 169 is disposed even closer to the active region 2N5. Therefore, it is possible to reduce a resistance value from the via 169 to the nanosheet 125, and thus it is possible to increase the speed of the semiconductor integrated circuit device.

### Configuration of 2-Input NAND Cell C11

The 2-input NAND cell C11 and the 2-input NAND cell C5 have substantially the same configuration. Specifically, the 2-input NAND cell C11 has the P-type transistors P11, P12 and the N-type transistors N11, N12, and forms the NAND circuit with the inputs A, B and the output Y.

As shown in FIG. 12(c) and 12(d), the 2-input NAND cell C11 has an active region 2P11, 2N11 which is different in width in the Y direction from the active region 2P5, 2N5 in the 2-input NAND cell C5 shown in FIG. 12(a) and 12(b).

Specifically, the width of the active region 2P11, 2N11 in the Y direction is w2. The width w2 is smaller than the width w1. That is, the drive capability of the 2-input NAND cell C5 is greater than the drive capability of the 2-input NAND cell C11.

As shown in FIG. 12, the lower end of the active region 2P11 (2N11) in the Y direction in the drawing is disposed at the same position in the Y direction as the lower end of the active region 2P5 (2N5) in the Y direction in the drawing. That is, the lower end of the active region 2P5 (2N5) of the 2-input NAND cell C5 in the Y direction in the drawing and the lower end of the active region 2P11 (2N11) of the 2-input NAND cell C11 in the Y direction in the drawing are aligned in the Y direction. In the 2-input NAND cell C5, C11, the lower surface of the nanosheets 123 (125) in the Y direction in the drawing is exposed from the gate line 134. In the 2-input NAND cell C5, C11, the lower surface of the nanosheets 124 (126) in the Y direction in the drawing is exposed from the gate line 135. That is, in the 2-input NAND cells C5, C11, the positions of the surfaces of the nanosheets exposed from the gate lines are aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

This embodiment employs an exemplary case in which the two 2-input NAND cells of which the active regions are different in width are disposed in the circuit block, but three or more 2-input NAND cells of which the active regions are different in width may be disposed in the circuit block. In this case, in each 2-input NAND cell, the positions of the surfaces of the nanosheets exposed from the gate line only need to be aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

Configuration of 2-input NOR Cell C6

As shown in FIG. 13(a), in the BM0 wiring layer, the power supply line 11 extending in the X direction is formed at an upper end portion of the cell in the Y direction in the drawing. The power supply line 11 supplies the power supply voltage VDD.

An active region 2P6 is formed in a P-type transistor region in the cell lower portion. In the active region 2P6, transistors P21, P22 are formed. The transistors P21, P22 have nanosheets 127, 128 extending in the X direction, respectively.

As shown in FIG. 13(b), an active region 2N6 is formed in an N-type transistor region in the cell upper portion. The active region 2N6 overlaps with the active region 2P6 in plan view.

In the active region 2N6, transistors N21, N22 are formed. The transistors N21, N22 have nanosheets 129, 130 extending in the X direction, respectively.

Gate lines 136, 137 extending in the Y direction are formed. The nanosheets 127, 129 overlap with the gate line 136 in plan view. The nanosheets 128, 130 overlap with the gate line 137 in plan view. The gate line 136 corresponds to the gates of the transistors P21, N21. The gate line 137 corresponds to the gates of the transistors P22, N22.

The gate line 136 covers the outer peripheries of the nanosheets 127, 129 in the Y direction and the Z direction so that part of the outer peripheries of the nanosheets 127, 129 is exposed. The gate line 137 covers the outer peripheries of the nanosheets 128, 130 in the Y direction and the Z direction so that part of the outer peripheries of the nanosheets 128, 130 is exposed. Specifically, the surfaces of the nanosheets 127, 129 that are located on the lower side in the Y direction in the drawing are exposed from the gate line 136, and the surfaces of the nanosheets 127, 129 that are located on the upper side in the Y direction in the drawing are covered with the gate line 136. The surfaces of the nanosheets 128, 130 that are located on the lower side in the Y direction in the drawing are exposed from the gate line 137, and the surfaces of the nanosheets 128, 130 that are located on the upper side in the Y direction in the drawing are covered with the gate line 137.

As shown in FIG. 13(a), local lines 149, 150 extending in the Y direction are formed in the cell lower portion. The local line 149 is connected with part of the active region 2P6 that serves as the source of the transistor P21. The local line 149 is connected with the power supply line 11 through a via 172. The via 172 is formed in a region in which the power supply line 11 and the local line 149 overlap with each other in plan view. That is, through the via 172 and the local line 149, the power supply line 11 is connected with part of the active region 2P6 that serves as the source of the transistor P21. The local line 150 is connected with part of the active region 2P6 that serves as the drain of the transistor P22.

As shown in FIG. 13(b), local lines 151 to 153 extending in the Y direction are formed in the cell upper portion. The local line 151 is connected with part of the active region 2N6 that serves as the source of the transistors N21, N22. The local line 152 is connected with part of the active region 2N6 that serves as the drain of the transistor N21. The local line 153 is connected with part of the active region 2N6 that serves as the drain of the transistor N22.

The power supply line 51 and the lines 52 to 54 extending in the X direction are formed in the M0 wiring layer. The power supply line 51 supplies the power supply voltage VSS. The line 52 corresponds to the input A, the line 53 corresponds to the output Y, and the line 54 corresponds to the input B.

The power supply line 51 is formed at an upper end portion of the cell in the Y direction in the drawing. Through the via 173 and the local line 151, the power supply line 51 is connected with part of the active region 2N6 that serves as the source of the transistors N21, N22. The via 173 is formed in a region in which the power supply line 51 and the local line 151 overlap with each other in plan view.

The line 52 is disposed near a center portion of the cell in the Y direction in the drawing. The line 52 is connected with the gate line 136 through a via 174. The via 174 is formed in a region in which the line 52 and the active region 2N6 overlap with each other in plan view.

The line 53 is disposed between the power supply line 51 and the line 52, 54 in plan view. Through vias 175 to 177 and the local lines 150, 152, the line 53 is connected with part of the active region 2P6 that serves as the drain of the transistor P22 and part of the active region 2N6 that serves as the drain of the transistor N21, N22.

The line 54 is disposed near a center portion of the cell in the Y direction in the drawing. The line 54 is connected with the gate line 137 through a via 177. The via 177 is formed in a region in which the line 54 and the active region 2N6 overlap with each other in plan view.

As described above, the 2-input NOR cell C6 has the P-type transistors P21, P22 and the N-type transistors N21, N22, and forms the NOR circuit with the inputs A, B and the output Y.

As shown in FIG. 13(a) and 13(b), the active regions 2P6, 2N6 in the 2-input NOR cell C6 has a width w1 in the Y direction in plan view.

In the 2-input NOR cell C6 shown in FIG. 13, the surfaces of the nanosheets 127, 129 that are located on the lower side in the Y direction in the drawing are exposed from the gate line 136. The surfaces of the nanosheets 128, 130 that are located on the lower side in the Y direction in the drawing are exposed from the gate line 137. The cell rows CR are disposed so that they are alternately inverted in the Y direction. That is, the cells adjacent to each other in the Y direction are disposed so that the nanosheets in the active regions face each other in the Y direction while the surfaces exposed from the gate line (the surfaces located on the lower side in the drawing) face each other in the Y direction. Accordingly, it is possible to shorten the distance d13 from the lower end of the active region 2P6 (2N6) in the Y direction in the drawing to the lower end of the cell frame in the Y direction in the drawing. In other words, the active regions 2P6, 2N6 (the nanosheets 127 to 130) can be disposed close to the lower end of the cell frame in the Y direction in the drawing. Therefore, the area of the semiconductor integrated circuit device can be reduced.

The surfaces of the nanosheets 127, 129 that are located on the upper side in the Y direction in the drawing are not exposed from the gate line 136. The surfaces of the nanosheets 128, 130 that are located on the upper side in the Y direction in the drawing are not exposed from the gate line 137. That is, the cells adjacent to each other in the Y direction are disposed so that the nanosheets in the active regions face each other in the Y direction while the surfaces exposed from the gate line (the surfaces located on the lower side in the drawing) face each other in the Y direction, and the surfaces not exposed from the gate line (the surfaces located on the upper side in the drawing) face each other in the Y direction. Thus, the distance d13 from the lower end of the active region 2P6 (2N6) in the Y direction in the drawing to the lower end of the cell frame in the Y direction in the drawing is smaller than the distance d14 from the upper end of the active region 2P6 (2N6) in the Y direction in the drawing to the upper end of the cell frame in the Y direction in the drawing. In other words, in plan view, the active region 2P6 (2N6) is disposed close to the lower end of the cell frame in the drawing with respect to the center of the cell frame in the Y direction in the drawing. That is, in plan view, the center portion of the active region 2P6 (2N6) in the Y direction in the drawing is located on the lower side in the drawing with respect to the center portion of the cell frame in the Y direction in the drawing.

In plan view, the power supply lines 11, 51 are formed at the upper end portion of the cell in the Y direction in the drawing, and are shared with the standard cell disposed on the upper side of the 2-input NOR cell C6 in the Y direction in the drawing. Accordingly, by the 2-input NOR cell C6 being disposed in the circuit block of FIG. 10, the power supply lines for supplying the power supply voltages VDD, VSS can be reinforced. Therefore, it is possible to reduce a decrease in the power supply voltage, and also it is possible to reduce occurrence of electromigration due to current concentration.

The power supply line 11 (51) does not overlap with the active region 2P6 (2N6) in plan view. Accordingly, it is possible to reduce the load capacitance by the power supply line 11 (51) that supplies the power supply voltage VDD (VSS) to the transistors P21, P22 (N21, N22) formed in the active region 2P6 (2N6), and therefore it is possible to increase the speed of the semiconductor integrated circuit device. The power supply line 11 (51) may overlap with the active region 2P6 (2N6) in plan view. In this case, the region in which the power supply line 11 (51) and the active region 2P6 (2N6) overlap with each other can be made smaller than the 2-input NOR cell C3 of FIG. 8, and therefore it is possible to increase the speed of the semiconductor integrated circuit device.

The via 174 (177) that connects the line 52 (54) and the gate line 136 (137) is formed in a region to overlap with the active region 2N6 and the gate line 136 (137) in plan view. Accordingly, it is possible to shorten the distance from the line 52 (54) (the input A (the input B)) to part of the gate line 136 (137) overlapping with the nanosheets 127, 129 (128, 130) in plan view that covers the nanosheets 127, 129 (128, 130). Therefore, it is possible to reduce a resistance value from the line 52 (54), and thus it is possible to increase the speed of the semiconductor integrated circuit device.

The line 53 is disposed on the upper side in the Y direction in the drawing with respect to the lines 52, 54 (the side on which the nanosheets 129, 130 are not exposed from the gate lines 136, 137 and which is opposite to the side on which the active region 2N6 is disposed close to the cell frame). The via 175 connects the line 53 and the local line 152 connected to part of the active region 2N6 that serves as the drain of the transistor N21. The via 176 connects the line 53 and the local line 153 connected to part of the active region 2N6 that serves as the drain of the transistor N22. The via 177 connects the line 153 and the local line 150 connected to part of the active region 2P6 that serves as the drain of the transistor P22. In plan view, the vias 175 o 177 are formed on the upper side in the Y direction in the drawing with respect to the lines 52, 54. Accordingly, it is possible to shorten the distance from the line 53 to part of the active region 2P6 that serves as the drain of the transistor P22 and the distance from the line 53 to part of the active region 2N6 that serves as the drain of the transistor N21, N22. Therefore, it is possible to reduce a resistance value from the line 53 to part of the active region 2P6 (2N6) that serves as the drain of the transistor P22 (N21, N22), and thus it is possible to increase the speed of the semiconductor integrated circuit device.

The via 172 that connects the power supply line 11 and the local line 149 connected with part of the active region 2P6 that serves as the source of the transistor P21 is formed in a region in which the power supply line 11 and the local line 149 overlap with each other in plan view. In plan view, the via 172 is disposed close to the lower side in the drawing in the region in which the power supply line 11 and the local line 149 overlap with each other in plan view. In other words, in plan view, the distance d15 in the Y direction from a center portion of the via 172 in the drawing to the lower end of the power supply line 11 in the drawing is smaller than the distance d16 in the Y direction from the center portion of the via 172 in the drawing to the upper end of the local line 149 in the drawing. Accordingly, the via 172 is disposed even closer to the active region 2P6. Therefore, it is possible to reduce a resistance value from the via 172 to the nanosheet 127, and thus it is possible to increase the speed of the semiconductor integrated circuit device.

The via 173 that connects the power supply line 51 and the local line 151 connected with part of the active region 2N6 that serves as the source of the transistors N21, N22 is formed in a region in which the power supply line 51 and the local line 151 overlap with each other in plan view. In plan view, the via 173 is disposed close to the lower side in the drawing in the region in which the power supply line 51 and the local line 151 overlap with each other in plan view. In other words, in plan view, the distance d15 in the Y direction from a center portion of the via 173 in the drawing to the lower end of the power supply line 51 in the drawing is smaller than the distance d16 in the Y direction from the center portion of the via 173 in the drawing to the upper end of the local line 151 in the drawing. Accordingly, the via 173 is disposed even closer to the active region 2N6. Therefore, it is possible to reduce a resistance value from the via 173 to the nanosheets 129, 130, and thus it is possible to increase the speed of the semiconductor integrated circuit device.

Configuration of 2-input NOR Cell C12

The 2-input NOR cell C12 and the 2-input NOR cell C6 have substantially the same configuration. Specifically, the 2-input NOR cell C12 has the P-type transistors P21, P22 and the N-type transistors N21, N22, and forms a NOR circuit with the inputs A, B and the output Y.

As shown in FIG. 13(c) and 13(d), the 2-input NOR cell C12 has an active region 2P12, 2N12 which is different in width in the Y direction from the active region 2P6, 2N6 in the 2-input NOR cell C6 shown in FIGS. 13(a) and 13(b).

Specifically, the width of the active region 2P12, 2N12 in the Y direction is w2. The width w2 is smaller than the width w1. That is, the drive capability of the 2-input NOR cell C6 is greater than the drive capability of the 2-input NOR cell C12.

As shown in FIG. 13, the lower end of the active region 2P12 (2N12) in the Y direction in the drawing is disposed at the same position in the Y direction as the lower end of the active region 2P6 (2N6) in the Y direction in the drawing. That is, the lower end of the active region 2P6 (2N6) of the 2-input NOR cell C6 in the Y direction in the drawing and the lower end of the active region 2P12 (2N12) of the 2-input NOR cell C12 in the Y direction in the drawing are aligned in the Y direction. In the 2-input NOR cell C6, C12, the lower surface of the nanosheet 127 (129) in the Y direction in the drawing is exposed from the gate line 136. In the 2-input NOR cell C6, C12, the lower surface of the nanosheet 128 (130) in the Y direction in the drawing is exposed from the gate line 137. That is, in the 2-input NOR cells C6, C12, the positions of the surfaces of the nanosheets exposed from the gate lines are aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

This embodiment employs an exemplary case in which the two 2-input NOR cells of which the active regions are different in width are disposed in the circuit block, but three or more 2-input NOR cells of which the active regions are different in width may be disposed in the circuit block. In this case, in each 2-input NOR cell, the positions of the surfaces of the nanosheets exposed from the gate line only need to be aligned in the Y direction. Accordingly, the shape of the structure comprised of an insulator and provided between the nanosheets exposed from the gate lines and facing each other, or in other words, the size and installation range in the Y direction, can be made constant. Therefore, the semiconductor integrated circuit device can be easily manufactured.

In the above embodiments and variations, each transistor includes three nanosheets, but some or all of the transistors may include one nanosheet, two nanosheets, four nanosheets, or more nanosheets.

In the above embodiments and variations, the cross-sectional shape of the nanosheet is rectangular, but is not limited to this shape. For example, the shape may be square, circular or elliptical.

In the above embodiments and variations, the P-type transistor is formed in the cell lower portion, and the N-type transistor is formed in the cell upper portion. Alternatively, the P-type transistor may be formed in the cell upper portion, and the N-type transistor may be formed in the cell lower portion.

In the above embodiments and variations, the power supply line 11 formed in the BM0 wiring layer and the power supply line 51 formed in the M1 wiring layer have the same line width, but the power supply lines 11, 51 may have different line widths.

In the 2-input NAND cells C2, C8, a via similar to the via 61a shown in FIG. 6, the length of which is greater in the Y direction than in the X direction, may be used instead of the vias 66 to 68. Similarly, in the 2-input l NOR cells C3, C9, a via similar to the via 61a shown in FIG. 6, the length of which is greater in the Y direction than in the X direction, may be used instead of the vias 73 to 75.

In the inverter cell C4, C10, a via similar to the via 61a shown in FIG. 6, the length of which is greater in the Y direction than in the X direction, may be used instead of the vias 161, 162. Similarly, in the 2-input NAND cell C5, C11, a via similar to the via 61a shown in FIG. 6, the length of which is greater in the Y direction than in the X direction, may be used instead of the vias 168, 169. Similarly, in the 2-input NOR cells C6, C12, a via similar to the via 61a shown in FIG. 6, the length of which is greater in the Y direction than in the X direction, may be used instead of the vias 172, 173.

Regarding a standard cell using a CFET, the present disclosure provides the layout of a semiconductor integrated circuit device including a standard cell using a forksheet transistor as a transistor, where it is possible to reduce a decrease in the power supply voltage, and also it is possible to reduce occurrence of electromigration due to current concentration.

What is claimed is:

1. A semiconductor integrated circuit device comprising: a plurality of standard cells including a first standard cell, wherein
the first standard cell includes
a first active region forming a channel, a source, and a drain of a first transistor of a first conductivity type and including a first nanosheet extending in a first direction as the channel,
a second active region formed above the first active region in a depth direction; overlapping with the first active region in plan view; forming a channel, a source, and a drain of a second transistor of a second conductivity type different from the first conductivity type; and including a second nanosheet extending in the first direction as the channel,
a first gate line extending in a second direction perpendicular to the first direction and the depth direction and surrounding outer peripheries of the first nanosheet and the second nanosheet in the second direction and the depth direction, and
a first power supply line formed on a back surface side of the first transistor; extending in the first direction; and supplying a first power supply voltage,
a surface of each of the first nanosheet and the second nanosheet that is located on a first side which is one side in the second direction is exposed from the first gate line, and
the first power supply line is disposed at an end portion of the first standard cell that is located on the first side.

2. The semiconductor integrated circuit device of claim 1, wherein
the plurality of standard cells include a second standard cell adjacent to part of the first standard cell that is located on the first side, and
the first power supply line is shared by the first standard cell and the second standard cell.

3. The semiconductor integrated circuit device of claim 1, wherein
the first standard cell further includes a first via formed in a region in which part of the first active region that serves as the source of the first transistor and the first power supply line overlap with each other, and connecting the part of the first active region that serves as the source of the first transistor and the first power supply line.

4. The semiconductor integrated circuit device of claim 3, wherein
in plan view, a distance from a center portion of the first via in the second direction to an end portion of the first power supply line that is located on a second side which is the other side in the second direction is smaller than a distance from the center portion of the first via in the second direction to an end portion of the first active region that is located on the first side.

5. The semiconductor integrated circuit device of claim 3, wherein
a length of the first via in the second direction is longer than a length of the first via in the first direction.

6. The semiconductor integrated circuit device of claim 1, wherein
the first standard cell further includes
a second power supply line formed above the second transistor in the depth direction; extending in the first direction; and supplying a second power supply voltage different from the first power supply voltage, and
a second via formed in a region in which part of the second active region that serves as the source of the second transistor and the second power supply line overlap with each other, and connecting the part of the second active region that serves as the source of the second transistor and the second power supply line.

7. The semiconductor integrated circuit device of claim 1, wherein
a distance from an end portion of the first active region that is located on the first side to the end portion of the first standard cell that is located on the first side is smaller than a distance from an end portion of the first active region that is located on a second side which is the other side in the second direction to an end portion of the first standard cell that is located on the second side.

8. The semiconductor integrated circuit device of claim 1, wherein
the plurality of standard cells include a second standard cell adjacent to part of the first standard cell that is located on the first side, and a third standard cell adjacent to part of the first standard cell that is located on a second side which is the other side in the second direction,
the second standard cell includes
a third active region forming a channel, a source, and a drain of a third transistor of the first conductivity type and including a third nanosheet extending in the first direction as the channel, and
a third gate line extending in the second direction and surrounding an outer periphery of the third nanosheet in the second direction and the depth direction,
the third standard cell includes
a fourth active region forming a channel, a source, and a drain of a fourth transistor of the first conductivity type and including a fourth nanosheet extending in the first direction as the channel, and
a fourth gate line extending in the second direction and surrounding an outer periphery of the fourth nanosheet in the second direction and the depth direction,
a surface of the third nanosheet that is located on the second side is exposed from the third gate line,
a surface of the fourth nanosheet that is located on the second side is exposed from the fourth gate line, and
a distance in the second direction between the first active region and the third active region is smaller than a distance in the second direction between the first active region and the fourth active region.

9. The semiconductor integrated circuit device of claim 1, wherein
the first active region forms a channel, a source, and a drain of a fifth transistor of the first conductivity type, and includes a fifth nanosheet extending in the first direction as the channel,
the second active region forms a channel, a source, and a drain of a sixth transistor of the second conductivity type, and includes a sixth nanosheet extending in the first direction as the channel,
the first standard cell includes a second gate line extending in the second direction and surrounding outer peripheries of the fifth nanosheet and the sixth nanosheet in the second direction and the depth direction, and
a surface of each of the fifth nanosheet and the sixth nanosheet that is located on the first side is exposed from the second gate line.

10. The semiconductor integrated circuit device of claim 1, wherein
the plurality of standard cells include a fourth standard cell with which the first standard cell is arranged in the first direction,
the fourth standard cell includes
a seventh active region forming a channel, a source, and a drain of a seventh transistor of the first conductivity type and including a seventh nanosheet extending in the first direction as the channel,
an eighth active region formed above the seventh active region in the depth direction; overlapping with the seventh active region in plan view; forming a channel, a source, and a drain of an eighth transistor of the second conductivity type; and including an eighth nanosheet extending in the first direction as the channel, and
a fifth gate line extending in the second direction and surrounding outer peripheries of the seventh nanosheet and the eighth nanosheet in the second direction and the depth direction,
a surface of each of the seventh nanosheet and the eighth nanosheet that is located on the first side is exposed from the fifth gate line,
in plan view, a width of the seventh nanosheet in the second direction is smaller than a width of the first nanosheet in the second direction, and
in plan view, an end portion of the first nanosheet that is located on the first side and an end portion of the seventh nanosheet that is located on the first side are disposed at the same position in the second direction.

11. A semiconductor integrated circuit device comprising: a plurality of standard cells including a first standard cell, wherein
the first standard cell includes
a first active region forming a channel, a source, and a drain of a first transistor of a first conductivity type and including a first nanosheet extending in a first direction as the channel,
a second active region formed above the first active region in a depth direction; overlapping with the first active region in plan view; forming a channel, a source, and a drain of a second transistor of a second conductivity type different from the first conductivity type; and including a second nanosheet extending in the first direction as the channel,
a first gate line extending in a second direction perpendicular to the first direction and the depth direction and surrounding outer peripheries of the first nanosheet and the second nanosheet in the second direction and the depth direction, and
a first power supply line formed on a back surface side of the first transistor; extending in the first direction; and supplying a first power supply voltage,
a surface of each of the first nanosheet and the second nanosheet that is located on a first side which is one side in the second direction is exposed from the first gate line, and
the first power supply line is disposed at an end portion of the first standard cell that is located on a second side which is the other side in the second direction.

12. The semiconductor integrated circuit device of claim 11, wherein
the plurality of standard cells include a third standard cell adjacent to part of the first standard cell that is located on the second side, and
the first power supply line is shared by the first standard cell and the third standard cell.

13. The semiconductor integrated circuit device of claim 11, wherein
in plan view, the first power supply line does not overlap with the first active region.

14. The semiconductor integrated circuit device of claim 11, wherein
the first standard cell further includes
a first line connected with part of the first active region that serves as the source of the first transistor, and
a second via formed in a region in which the first line and the first power supply line overlap with each other in plan view and connecting the first line and the first power supply line.

15. The semiconductor integrated circuit device of claim 14, wherein
in plan view, a distance from a center portion of the second via in the second direction to an end portion of the first power supply line that is located on the first side is smaller than a distance from the center portion of the second via in the second direction to an end portion of the first line that is located on the second side.

16. The semiconductor integrated circuit device of claim 11, wherein
the first standard cell further includes a second power supply line formed above the second transistor in the depth direction; extending in the first direction; and supplying a second power supply voltage different from the first power supply voltage.

17. The semiconductor integrated circuit device of claim 11, wherein
a distance from an end portion of the first active region that is located on the first side to the end portion of the first standard cell that is located on the first side is smaller than a distance from an end portion of the first active region that is located on the second side to an end portion of the first standard cell that is located on the second side.

18. The semiconductor integrated circuit device of claim 11, wherein
the plurality of standard cells include a second standard cell adjacent to part of the first standard cell that is located on the first side, and a third standard cell adjacent to part of the first standard cell that is located on the second side,
the second standard cell includes
a third active region forming a channel, a source, and a drain of a third transistor of the first conductivity type and including a third nanosheet extending in the first direction as the channel, and
a third gate line extending in the second direction and surrounding an outer periphery of the third nanosheet in the second direction and the depth direction,
the third standard cell includes
a fourth active region forming a channel, a source, and a drain of a fourth transistor of the first conductivity type and including a fourth nanosheet extending in the first direction as the channel, and
a fourth gate line extending in the second direction and surrounding an outer periphery of the fourth nanosheet in the second direction and the depth direction,
a surface of the third nanosheet that is located on the second side is exposed from the third gate line,
a surface of the fourth nanosheet that is located on the second side is exposed from the fourth gate line, and
a distance in the second direction between the first active region and the third active region is smaller than a distance in the second direction between the first active region and the fourth active region.

19. The semiconductor integrated circuit device of claim 11, wherein
the first active region forms a channel, a source, and a drain of a fifth transistor of the first conductivity type, and includes a fifth nanosheet extending in the first direction as the channel,
the second active region forms a channel, a source, and a drain of a sixth transistor of the second conductivity type, and includes a sixth nanosheet extending in the first direction as the channel,
the first standard cell includes a second gate line extending in the second direction and surrounding outer peripheries of the fifth nanosheet and the sixth nanosheet in the second direction and the depth direction, and
a surface of each of the fifth nanosheet and the sixth nanosheet that is located on the first side is exposed from the second gate line.

20. The semiconductor integrated circuit device of claim 11, wherein
the plurality of standard cells include a fourth standard cell with which the first standard cell is arranged in the first direction,
the fourth standard cell includes
a seventh active region forming a channel, a source, and a drain of a seventh transistor of the first conductivity type and including a seventh nanosheet extending in the first direction as the channel,
an eighth active region formed above the seventh active region in the depth direction; overlapping with the seventh active region in plan view; forming a channel, a source, and a drain of an eighth transistor of the second conductivity type; and including an eighth nanosheet extending in the first direction as the channel, and
a fifth gate line extending in the second direction and surrounding outer peripheries of the seventh nanosheet and the eighth nanosheet in the second direction and the depth direction,
a surface of each of the seventh nanosheet and the eighth nanosheet that is located on the first side is exposed from the fifth gate line,
in plan view, a width of the seventh nanosheet in the second direction is smaller than a width of the first nanosheet in the second direction, and
in plan view, an end portion of the first nanosheet that is located on the first side and an end portion of the seventh nanosheet that is located on the first side are disposed at the same position in the second direction.
